(19) United States
(12) Patent Application Publication
(10) Pub. No.: US 2025/0169218 A1
(43) Pub. Date: May 22, 2025

(54) SOLID-STATE IMAGING DEVICE

(71) Applicant: SONY SEMICONDUCTOR SOLUTIONS CORPORATION, KANAGAWA (JP)

(72) Inventors: HIROSHI TAKAHASHI, KANAGAWA (JP); YOSHIAKI KITANO, KANAGAWA (JP)

(21) Appl. No.: 18/836,176

(22) PCT Filed: Dec. 27, 2022
(86) PCT No.: PCT/JP2022/048312

§ 371 Date: Aug. 6, 2024

(30) Foreign Application Priority Data
Feb. 14, 2022 (JP) 2022-020873

(51) Int. Cl. H10F 39/00; H10F 39/18

(52) U.S. Cl. CPC H10F 39/813; H10F 39/014; H10F 39/182; H10F 39/807

(57) ABSTRACT

A solid-state imaging device includes: a first pixel including a first photoelectric conversion element that is disposed on a side of a first surface of a base and converts light into electric charge, the side of the first surface being a light incident side; a second pixel being adjacent to the first pixel, and including a second photoelectric conversion element that is disposed on the side of the first surface of the base and converts light into electric charge; a first transistor disposed at a position corresponding to the first pixel on a side of a second surface of the base, the first transistor including a pair of main electrodes; a second transistor disposed at a position corresponding to the second pixel on the side of the second surface of the base, the second transistor including a pair of main electrodes; a pixel separation region disposed between the first pixel and the second pixel; and a shared coupling section having one end electrically coupled directly to one of the main electrodes of the first transistor, and another end electrically coupled, across the pixel separation region, directly to one of the main electrodes of the second transistor.

### TECHNICAL FIELD

The present disclosure relates to a solid-state imaging device.

### BACKGROUND ART

PTL 1 discloses a CMOS (Complementary Metal Oxide Semiconductor) image sensor. In the image sensor, a separation pattern that separates pixels from each other is formed by using a trench that penetrates a substrate. The pixel includes a photoelectric conversion region formed in the substrate of which a periphery is surrounded by the separation pattern.

Electric charge converted from light by the photoelectric conversion region is transferred to a pixel circuit through a transfer transistor and a floating diffusion diffusing region. The pixel circuit includes a source follower transistor, a reset transistor, and a select transistor. The pixel circuit is formed on a main surface of the substrate in a region of which a periphery is surrounded by the separation pattern.

### CITATION LIST

### Patent Literature

PTL1: International Publication No. WO2019/220945

### SUMMARY OF THE INVENTION

In an image sensor, advancement in miniaturization of a pixel makes it difficult to dispose a plurality of transistors constructing a pixel circuit, in a region corresponding to one pixel. Accordingly, the plurality of transistors is separately disposed in a plurality of regions corresponding to a plurality of pixels.

A separation pattern is formed between the pixels. This allows main electrodes of the plurality of transistors to be coupled to each other through wiring over the separation pattern. The wiring is disposed on the separation pattern with an insulating film interposed therebetween, and is coupled to the main electrodes through a coupling hole formed in the insulating film. In manufacturing of the image sensor, the coupling hole is formed with an alignment margin dimension, which increases an area necessary to couple the main electrodes and the wiring to each other. Meanwhile, a dimension of a gate length and a dimension of a gate width reduce that determine an electrical property of the transistors.

Therefore, it is desired to improve an electrical property of a transistor while securing an area sufficient to dispose the transistor.

A solid-state imaging device according to an embodiment of the present disclosure includes: a first pixel including a first photoelectric conversion element that is disposed on a side of a first surface of a base and converts light into electric charge, the side of the first surface being a light incident side; a second pixel being adjacent to the first pixel, and including a second photoelectric conversion element that is disposed on the side of the first surface of the base and converts light into electric charge; a first transistor disposed at a position corresponding to the first pixel on a side of a second surface of the base, the first transistor including a pair of main electrodes, the side of the second surface being a side opposite to the first surface; a second transistor disposed at a position corresponding to the second pixel on the side of the second surface of the base, the second transistor including a pair of main electrodes; a pixel separation region disposed between the first photoelectric conversion element and the first transistor and between the second photoelectric conversion element and the second transistor, the pixel separation region electrically and optically separating the first photoelectric conversion element and the first transistor from each other and electrically and optically separating the second photoelectric conversion element and the second transistor from each other; and a shared coupling section having one end electrically coupled directly to one of the main electrodes of the first transistor, and another end electrically coupled, across the pixel separation region, directly to one of the main electrodes of the second transistor.

### BRIEF DESCRIPTION OF THE DRAWINGS

FIG. 1 is a circuit diagram illustrating pixels and a pixel circuit of a solid-state imaging device according to a first embodiment of the present disclosure.

FIG. 2 is a planar configuration diagram of a transistor constructing the pixel circuit illustrated in FIG. 1.

FIG. 3 is a specific planar configuration diagram of the pixel circuit illustrated in FIG. 1.

FIG. 4 is a vertical cross-sectional configuration diagram of a portion of the pixels and the pixel circuit illustrated in FIG. 1 (a cross-sectional view sectioned along a section line A-A illustrated in FIG. 3).

FIG. 5 is a vertical cross-sectional configuration diagram of another portion of the pixels and the pixel circuit illustrated in FIG. 1 (a cross-sectional view sectioned along a section line B-B illustrated in FIG. 3).

FIG. 6 is an explanatory first step cross-sectional view (a cross-sectional view sectioned along a section line C-C illustrated in FIG. 3) of a manufacturing method of the solid-state imaging device according to the first embodiment.

FIG. 7 is a second step cross-sectional view.

FIG. 8 is a third step cross-sectional view.

FIG. 9 is a fourth step cross-sectional view.

FIG. 10 is a fifth step cross-sectional view.

FIG. 11 is a sixth step cross-sectional view.

FIG. 12 is a vertical cross-sectional configuration diagram corresponding to FIG. 11 of a portion of pixels and a pixel circuit of a solid-state imaging device according to a second embodiment of the present disclosure.

FIG. 13 is an explanatory first step cross-sectional view corresponding to FIG. 6 of a manufacturing method of the solid-state imaging device illustrated in FIG. 12.

FIG. 14 is a second step cross-sectional view.

FIG. 15 is a third step cross-sectional view.

FIG. 16 is a fourth step cross-sectional view.

FIG. 17 is a fifth step cross-sectional view.

FIG. 18 is a planar configuration diagram corresponding to FIG. 3 of a pixel circuit of a solid-state imaging device according to a third embodiment of the present disclosure.

FIG. 19 is a vertical cross-sectional configuration diagram corresponding to FIG. 4 of a portion of the pixels and the pixel circuit of the solid-state imaging device illustrated in FIG. 18 (a cross-sectional view sectioned along a section line D-D illustrated in FIG. 18).

FIG. 20 is a vertical cross-sectional configuration diagram of another portion of the pixels and the pixel circuit of the solid-state imaging device illustrated in FIG. 18 (a cross-sectional view sectioned along a section line E-E illustrated in FIG. 18).

FIG. 21 is a circuit diagram corresponding to FIG. 1 illustrating pixels and a pixel circuit of a solid-state imaging device according to a fourth embodiment of the present disclosure.

FIG. 22 is a specific planar layout configuration diagram of the pixels and the pixel circuits illustrated in FIG. 21.

FIG. 23 is a specific planar configuration diagram corresponding to FIG. 3 of a pixel circuit of a solid-state imaging device according to a fifth embodiment of the present disclosure.

FIG. 24 is a specific planar layout configuration diagram corresponding to FIG. 23 of pixel circuits of a solid-state imaging device according to a sixth embodiment of the present disclosure.

FIG. 25 is a planar layout configuration diagram of color filters to be disposed at pixels illustrated in FIG. 24.

FIG. 26 is a planar layout configuration diagram of the pixels illustrated in FIG. 24, at which red and blue filters are disposed.

FIG. 27 is a planar layout configuration diagram of the pixels illustrated in FIG. 24, at which green filters (red side and blue side) are disposed.

FIG. 28 is a planar layout configuration diagram of a dummy pixel and a dummy pixel circuit among the pixels and the pixel circuits illustrated in FIG. 24.

FIG. 29 is a planar layout configuration diagram of optical lenses to be disposed at the pixels illustrated in FIG. 24.

FIG. 30 is a block diagram depicting an example of schematic configuration of a vehicle control system.

FIG. 31 is a diagram of assistance in explaining an example of installation positions of an outside-vehicle information detecting section and an imaging section.

### MODES FOR CARRYING OUT THE INVENTION

Hereinafter, detailed description is given of embodiments of the present disclosure with reference to the drawings. It is to be noted that the description is given in the following order.

### 1. First Embodiment

A first embodiment describes an example in which the present technology is applied to a solid-state imaging device. The first embodiment describes, in detail, a circuit configuration, a planar configuration, and a vertical cross-sectional configuration of pixels and a pixel circuit of the solid-state imaging device, and a manufacturing method of the solid-state imaging device.

### 2. Second Embodiment

A second embodiment describes an example in which a configuration of shared coupling sections is changed in the solid-state imaging device according to the first embodiment. The second embodiment describes, in detail, each of the vertical cross-sectional configuration of the pixels and the pixel circuit of the solid-state imaging device and the manufacturing method of the solid-state imaging device.

### 3. Third Embodiment

A third embodiment describes an example in which a planar shape of transistors of the pixel circuit is changed in the solid-state imaging device according to the first embodiment.

### 4. Fourth Embodiment

A fourth embodiment describes an example in which the circuit configuration of the pixel circuit is changed in the solid-state imaging device according to the first embodiment or the second embodiment. The fourth embodiment describes each of the circuit configuration and a planar layout configuration of the pixels and the pixel circuit.

### 5. Fifth Embodiment

A fifth embodiment describes an example in which a planar layout configuration of the transistors of the pixel circuit is changed in the solid-state imaging device according to the first embodiment.

### 6. Sixth Embodiment

A sixth embodiment describes a practical application example of the solid-state imaging device according to the fifth embodiment. The sixth embodiment describes the planar layout configuration of the pixels and the pixel circuit, a planar layout configuration of color filters, and a planar layout configuration of optical lenses.

### 7. Example of Practical Application to Mobile Body

Description is given of an example in which the present technology is applied to a vehicle control system that is an example of a mobile body control system.

### 8. Other Embodiments

### 1. First Embodiment

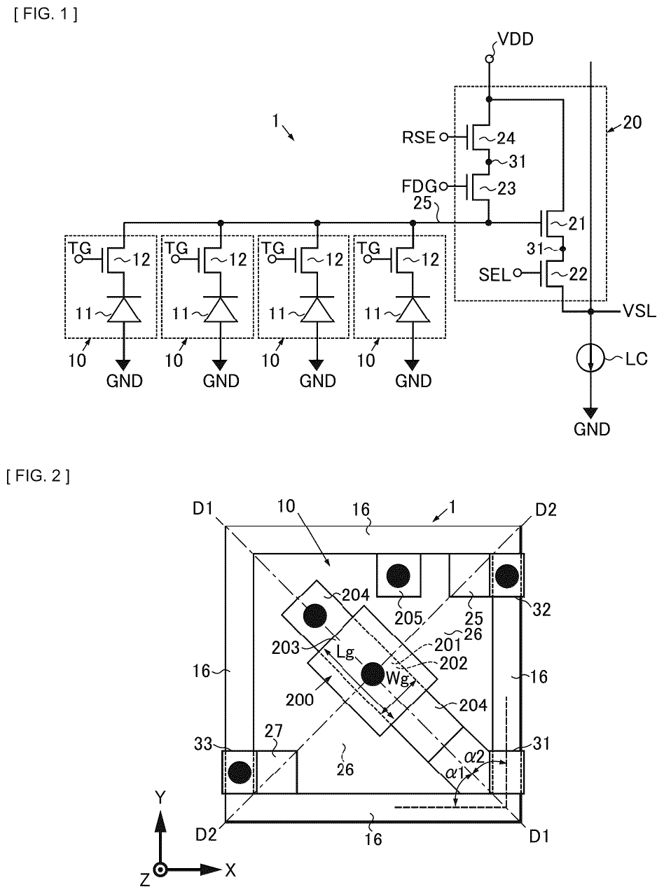

Description is given of a solid-state imaging device 1 according to the first embodiment of the present disclosure with reference to FIGS. 1 to 11.

Here, an arrow-X direction illustrated as appropriate in the drawings indicates one planar direction of the solid-state imaging device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each illustrated to aid understanding of description, and are not intended to limit directions used in the present technology.

### [Configuration of Solid-State Imaging Device 1]

### (1) Circuit Configuration of Pixel 10 and Pixel Circuit 20 of Solid-State Imaging Device 1

FIG. 1 illustrates an example of a circuit configuration of pixels 10 and a pixel circuit 20 constructing the solid-state imaging device 1.

One pixel 10 includes a series circuit of a photoelectric conversion element (a photodiode) 11 and a transfer transistor 12. Here, four pixels 10 are configured as a unit pixel.

The photoelectric conversion element 11 converts, into electric charge (an electric signal), light incident from the outside of the solid-state imaging device 1.

The transfer transistor 12 includes a gate electrode and a pair of main electrodes. One main electrode of the pair of main electrodes is coupled to the photoelectric conversion element 11. Another main electrode thereof is coupled to the pixel circuit 20 through a floating diffusion region (hereinafter, simply referred to as an “FD region”) 25. The gate electrode is coupled to an unillustrated horizontal signal line. A control signal TG is inputted to the gate electrode from the horizontal signal line.

Here, the pixel circuit 20 is disposed for every unit pixel. That is, one pixel circuit 20 is disposed for four pixels 10. The pixel circuit 20 performs signal processing on the electric charge converted from the light in the pixel 10.

In the first embodiment, the pixel circuit 20 is constructed to include four transistors, i.e., a first transistor to a fourth transistor.

Here, the first transistor includes an amplification transistor 21 including a gate electrode and a pair of main electrodes. The second transistor includes a selection transistor 22 including a gate electrode and a pair of main electrodes. The third transistor includes a floating diffusion conversion gain switching transistor (hereinafter, simply referred to as an “FD conversion gain switching transistor”) 23 including a gate electrode and a pair of main electrodes. In addition, the fourth transistor includes a reset transistor 24 including a gate electrode and a pair of main electrodes.

The gate electrode of the amplification transistor 21 is coupled to the FD region 25. One of the main electrodes of the amplification transistor 21 is coupled to a power supply voltage terminal VDD, and another one of the main electrodes thereof is coupled to one of the main electrodes of the selection transistor 22.

The gate electrode of the selection transistor 22 is coupled to a selection signal line SEL. Another one of the main electrodes of the selection transistor 22 is coupled to a vertical signal line VSL and a current source load LC. The current source load LC is coupled to a reference voltage terminal GND.

The gate electrode of the FD conversion gain switching transistor 23 is coupled to a floating diffusion control signal line FDG. One of the main electrodes of the FD conversion gain switching transistor 23 is coupled to the FD region 25, and another one of the main electrodes thereof is coupled to one of the main electrodes of the reset transistor 24.

The gate electrode of the reset transistor 24 is coupled to a reset signal line RST. Another one of the main electrodes of the reset transistor 24 is coupled to the power supply voltage terminal VDD.

In the solid-state imaging device 1, the pixel circuit 20 is further coupled to an unillustrated image processing circuit. The image processing circuit includes, for example, an analog/digital converter (ADC) and a digital signal processor (DSP).

The electric charge converted from the light by the pixel 10 is an analog signal. The analog signal is subjected to amplification processing in the pixel circuit 20. The ADC converts into a digital signal the analog signal outputted from the pixel circuit 20. The DSP performs functional processing on the digital signal. That is, the image processing circuit performs signal processing adapted to create an image.

### (2) Basic Layout Configuration of Pixel 10 and Transistor 200 Constructing Pixel Circuit 20

FIG. 2 illustrates an example of a basic configuration of the pixel 10 and a transistor 200 constructing the pixel circuit 20.

One pixel 10 and the transistor 200 constructing the pixel circuit 20 are disposed in a region of which a periphery is surrounded by a pixel separation region 16, as viewed in the arrow-Z direction (hereinafter, simply referred to as “in a plan view”). An opposite side in the arrow-Z direction is configured as a light incident surface. The photoelectric conversion element 11 constructing the pixel 10 is disposed on a side of the light incident surface.

The pixel separation region 16 extends in the arrow-X direction with a constant width dimension, and the plurality of pixel separation regions 16 is arranged in the arrow-Y direction with a constant spaced dimension. Further, the pixel separation region 16 similarly extends in the arrow-Y direction with a constant width dimension, and the plurality of pixel separation regions 16 is arranged in the arrow-X direction with a constant spaced dimension. That is, the pixel separation region 16 is disposed in a grid shape, and the pixel 10 and the transistor 200 are disposed in a region partitioned by the pixel separation region 16.

Although not particularly limited, the pixel 10 and the transistor 200 are disposed in a region partitioned into a square shape by the pixel separation region 16 in a plan view in the first embodiment. Here, one pixel 10 is disposed in one region partitioned by the pixel separation region 16. In addition, one transistor 200 constructing the pixel circuit 20 is disposed in the one region partitioned by the pixel separation region 16.

It is to be noted that description is given later of a vertical cross-sectional structure of each of the pixel separation region 16 and the transistor 200.

The transistor 200 includes the first transistor, the second transistor, the third transistor, or the fourth transistor. That is, the transistor 200 includes one of the amplification transistor 21, the selection transistor 22, the FD conversion gain switching transistor 23, or the reset transistor 24.

A periphery of the transistor 200 is surrounded by an element separation region 26. This allows the transistor 200 to be electrically and optically separated from another region. The transistor 200 includes a channel formation region 201, a gate insulating film 202, a gate electrode 203, and a pair of main electrodes 204. The main electrodes 204 are each formed by an n-type semiconductor region of a first electrically conductive type, and are each used as a source electrode or a drain electrode.

Here, the transistor 200 is an n-channel insulated gate field effect transistor (IGFET: Insulated Gate Field Effect Transistor). The IGFET includes a metal body-oxide film-semiconductor field effect transistor (MOSFET: Metal Oxide Semiconductor Field Effect Transistor) and a metal body-insulator-semiconductor field effect transistor (MISFET: Metal Insulator Semiconductor Field Effect Transistor).

The transistor 200 is disposed in a region corresponding to the pixel 10 in an oblique direction with respect to an extending direction of the pixel separation region 16.

To give detailed description, the transistor 200 is disposed in the region partitioned by the pixel separation region 16 (a region having a square shape in a plan view) to allow a direction of a gate length Lg to coincide with a diagonal D1-D1 illustrated as an imaginary line. The diagonal D1-D1 is from an upper left side to a lower right side. The gate length Lg is an effective length of the gate electrode 203 between the pair of main electrodes 204. In addition, a gate width Wg is a length in a direction being orthogonal to the direction of the gate length Lg and coinciding with a diagonal D2-D2 illustrated as an imaginary line. The diagonal D2-D2 is from a lower left side to an upper right side.

Here, the smallest angle α1 formed between the diagonal D1-D1 and the pixel separation region 16 extending in the arrow-X direction is 45 degrees. The largest angle is 135 degrees. As a matter of course, the smallest angle α2 formed between the diagonal D1-D1 and the pixel separation region 16 extending in the arrow-Y direction is 45 degrees. Setting the angle α1 to 45 degrees enables a dimension of the gate length Lg and a dimension of the gate width Wg of the transistor 200 to take a maximum value.

It is to be noted that it is possible to appropriately set the angle α1 at an angle of 30 degrees or more and less than 90 degrees. In other words, disposing the transistor 200 obliquely makes it possible to increase the gate length Lg and the gate width Wg of the transistor 200, as compared with a case where the transistor 200 is not disposed obliquely.

Meanwhile, the FD region 25 and a base coupling section 27 are disposed to coincide with the diagonal D2-D2 in the region partitioned by the pixel separation region 16.

The FD region 25 is disposed at a corner on an upper right side where the pixel separation region 16 extending in the arrow-X direction and the pixel separation region 16 extending in the arrow-Y direction intersect each other. The FD region 25 is formed by an n-type semiconductor region. The FD region 25 is disposed with respect to the transistor 200 with the element separation region 26 interposed therebetween.

Further, a vertical gate electrode 205 is disposed at a position spaced on a left side of the FD region 25. The vertical gate electrode 205 is a gate electrode of the transfer transistor 200, and extends in a base 15 by having the direction of the gate length Lg in a thickness direction of the base 15.

The base coupling section 27 is disposed at a corner on a lower left side where the pixel separation region 16 extending in the arrow-X direction and the pixel separation region 16 extending in the arrow-Y direction intersect each other. The base coupling section 27 is formed by a p-type semiconductor region of a second electrically conductive type. In the first embodiment, the base 15 is formed as a p-type well region. That is, the base 15 is coupled to the reference voltage terminal GND with the base coupling section 27 interposed therebetween. The base coupling section 27 is disposed with respect to the transistor 200 with the element separation region 26 interposed therebetween, in a similar manner to the FD region 25.

It is to be noted that a portion indicated by a black circle in FIG. 2 is a coupling region (a contact region) of the transistor 200 with wiring disposed in an upper layer on a side opposite to the photoelectric conversion element 11. The wiring is, for example, wiring 7 illustrated in FIG. 4. For example, copper (Cu) wiring is used as the wiring. The coupling region is, for example, a coupling hole 6H illustrated in FIG. 4.

### (3) Basic Layout Configuration of Shared Coupling Sections 31 to 33

A shared coupling (Shared Contact) section 31, a shared coupling section 32, and a shared coupling section 33 are disposed between or among the plurality of pixels 10.

Here, the shared coupling section 31 is disposed between the transistor 200 of the pixel 10 and the transistor 200 of another unillustrated pixel 10 adjacent thereto in the arrow-X direction. To give detailed description, one end of the shared coupling section 31 is electrically coupled directly to one of the main electrodes 204 of the transistor 200, and another end of the shared coupling section 31 is electrically coupled, across the pixel separation region 16, directly to one of the main electrodes of the other transistor 200. That is, the shared coupling section 31 directly couples the main electrodes 204 of the transistors 200 to each other over the pixel separation region 16 without forming wiring on the transistors 200 and a coupling hole formed in an interlayer insulating film between the transistors 200 and the wiring.

Here, the shared coupling section 32 is disposed among the FD region 25 of the pixel 10 and the FD regions 25 of other unillustrated pixels 10 adjacent thereto in the arrow-X direction and the arrow-Y direction. To give detailed description, the shared coupling section 32 is formed across the FD regions 25 of a total of four pixels 10 adjacent to each other in the arrow-X direction and the arrow-Y direction, and is electrically coupled directly to a total of four FD regions 25.

Here, the shared coupling section 33 is disposed among the base coupling section 27 of the pixel 10 and the base coupling sections 27 of other unillustrated pixels 10 adjacent thereto in the arrow-X direction and the arrow-Y direction. The shared coupling section 33 is formed across the base coupling sections 27 of a total of four pixels 10 adjacent to each other in the arrow-X direction and the arrow-Y direction, and is electrically coupled directly to a total of four base coupling sections 27, in a similar manner to the shared coupling section 32.

### (4) Layout Configuration and Vertical Cross-Sectional Configuration of Pixel 10 and Pixel Circuit 20

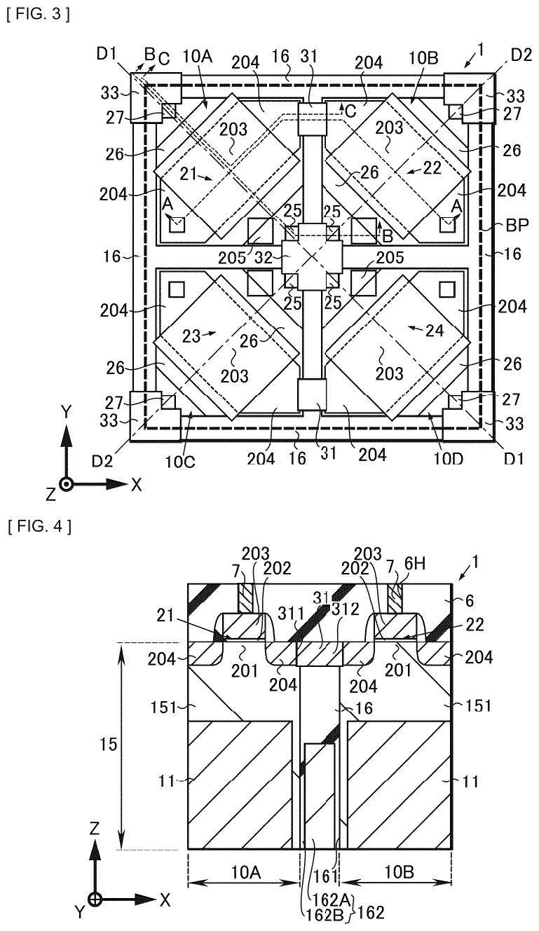

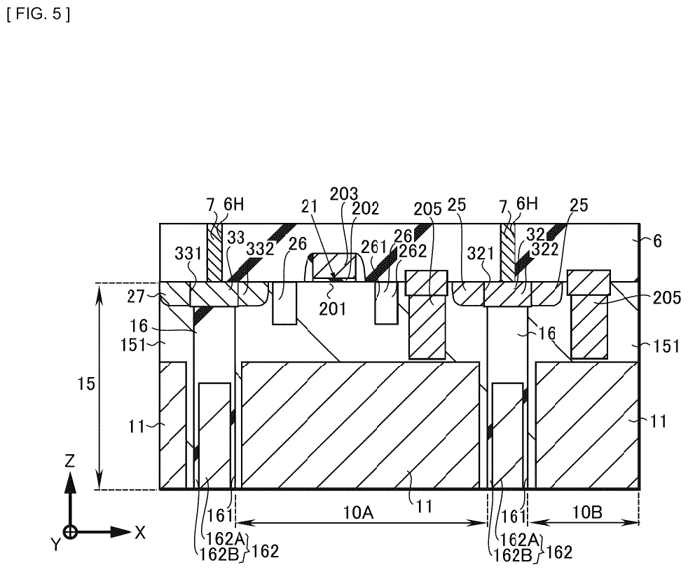

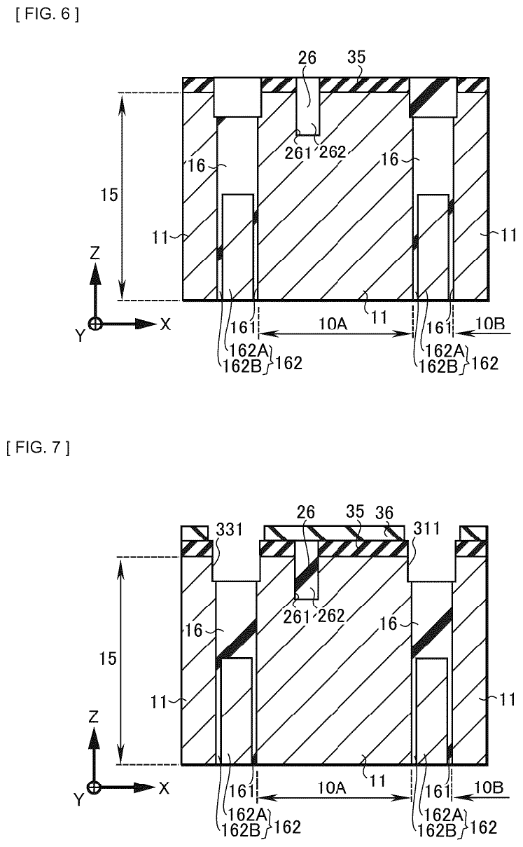

FIG. 3 illustrates an example of a specific planar configuration of the pixels 10 and the pixel circuit 20. FIG. 4 illustrates a vertical cross-sectional configuration of a portion of the pixels 10 and the pixel circuit 20 (a cross-section sectioned along a section line A-A illustrated in FIG. 3). FIG. 5 illustrates a vertical cross-sectional configuration of another portion of the pixels 10 and the pixel circuit 20 (a cross-section sectioned along a section line B-B illustrated in FIG. 3).

In the first embodiment, one pixel circuit 20 is disposed for four pixels 10, as illustrated in FIG. 3. To give detailed description, the four pixels 10 are two pixels, i.e., a pixel 10A and a pixel 10B, and two pixels, i.e., a pixel 10C and a pixel 10D. The pixel 10A and the pixel 10B are adjacent to each other in the arrow-X direction. The pixel 10C and the pixel 10D are adjacent to the pixel 10A and pixel 10B on an opposite side in the arrow-Y direction, and are adjacent to each other in the arrow-X direction. The four pixels, i.e., the pixel 10A, the pixel 10B, the pixel 10C, and the pixel 10D, construct a unit pixel BP.

The amplification transistor 21 of the pixel circuit 20 is disposed at a position corresponding to the pixel 10A. The amplification transistor 21 is disposed in the region partitioned by the pixel separation region 16 to allow the direction of the gate length Lg to coincide with the diagonal D2-D2.

The amplification transistor 21 is disposed on a main surface part of the base 15 on a side opposite to a light incident side (a second surface serving as an upper surface of the base 15 in FIG. 4), as illustrated in FIG. 5.

Here, for example, a semiconductor substrate is used for the base 15. To give further detailed description, a monocrystalline silicon substrate including a p-type semiconductor region (or a p-type well region) 151 is used. The photoelectric conversion element 11 is disposed on the light incident side of the base 15 (a side of a first surface serving as a lower surface of the base 15 in FIG. 4). The photoelectric conversion element 11 is formed at a pn junction between the p-type semiconductor region 151 and an n-type semiconductor region with no reference numeral.

Here, the pixel separation region 16 has a first trench 161 and includes a first embedded member 162. The first trench 161 is formed as a deep trench penetrating in the thickness direction from the upper surface to the lower surface of the base 15. The first embedded member 162 is embedded in the first trench 161. Here, the first embedded member 162 includes an insulator 162A provided along an inner wall of the first trench 161, and an embedded member 162B embedded in the first trench 161 with the insulator 162A interposed therebetween. For example, a silicon oxide film or a silicon nitride film is used for the insulator 162A. For example, a polycrystalline silicon film is used for the embedded member 162B. That is, the pixel separation region 16 has a trench isolation structure.

Further, although detailed illustration and description are omitted here, a pinning region is disposed in a region corresponding to the photoelectric conversion element 11 between the photoelectric conversion element 11 and the pixel separation region 16 inside the base 15.

The amplification transistor 21 includes the channel formation region 201, the gate insulating film 202, the gate electrode 203, and the pair of main electrodes 204, as described above for the transistor 200.

The channel formation region 201 is formed by the p-type semiconductor region 151 of the base 15.

The gate insulating film 202 is formed on a surface of the channel formation region 201. For example, a single layer film such as a silicon oxide film, a silicon nitride film, or an oxynitride film, or a composite film thereof is used for the gate insulating film 202.

The gate electrode 203 is formed on a surface of the gate insulating film 202 on a side opposite to the channel formation region 201. For example, a single layer film such as a polycrystalline silicon film, a high-melting-point metal film, a high-melting-point metal silicide film of a compound of polycrystalline silicon and high-melting-point metal, or a composite film thereof is used for the gate electrode 203. It is to be noted that a sidewall spacer with no reference numeral is formed on a side wall of the gate electrode 203.

The pair of main electrodes 204 is disposed in the main surface part of the base 15 in the direction of the gate length Lg centering around the gate electrode 203, and is each formed by an n-type semiconductor region.

The FD region 25 and the base coupling section 27 are disposed at respective positions coinciding with the diagonal D1-D1 and opposed to each other centering around the amplification transistor 21, as illustrated in FIG. 3. Each element separation region 26 is formed between the FD region 25 and the amplification transistor 21 and between the base coupling section 27 and the amplification transistor 21.

The FD region 25 is disposed in the main surface part of the base 15, and is formed by an n-type semiconductor region, in a similar manner to the main electrodes 204 of the amplification transistor 21.

The base coupling section 27 is disposed in the main surface part of the base 15, and is formed by a p-type semiconductor region having higher impurity density than the p-type semiconductor region 151 of the base 15.

The element separation region 26 has a second trench 261 and includes a second embedded member 262, as illustrated in FIG. 5. The second trench 261 is a trench formed in the thickness direction from the upper surface to a side of the lower surface of the base 15. The second trench 261 is such a trench that does not reach the photoelectric conversion element 11, and a depth of the second trench 261 is shallower than a depth of the first trench 161. The second embedded member 262 is embedded in the second trench 261. The second embedded member 262 is formed by, for example, a silicon oxide film, in a similar manner to the insulator 162A.

Referring back to FIG. 3, the selection transistor 22 of the pixel circuit 20 is disposed at a position corresponding to the pixel 10B. The selection transistor 22 is disposed in the region partitioned by the pixel separation region 16 to allow the direction of the gate length Lg to coincide with the diagonal D1-D1.

The selection transistor 22 is disposed on the main surface part of the base 15, in a similar manner to the amplification transistor 21, as illustrated in FIG. 5.

The selection transistor 22 includes the channel formation region 201, the gate insulating film 202, the gate electrode 203, and the pair of main electrodes 204, in a similar manner to the amplification transistor 21.

The FD region 25 and the base coupling section 27 are disposed at respective positions coinciding with the diagonal D2-D2 and opposed to each other centering around the selection transistor 22, as illustrated in FIG. 3. Each element separation region 26 is formed between the FD region 25 and the selection transistor 22 and between the base coupling section 27 and the selection transistor 22.

The selection transistor 22 is formed in a shape in line symmetry with the amplification transistor 21 centering around the pixel separation region 16 extending in the arrow-Y direction, in a plan view. This allows one of the main electrodes 204 of the selection transistor 22 to be disposed at a position with respect to one of the main electrodes 204 of the amplification transistor 21 with the pixel separation region 16 interposed therebetween in the arrow-X direction. The one of the main electrodes (an input electrode or a drain electrode) 204 of the selection transistor 22 and the one of the main electrodes (an output electrode or a source electrode) 204 of the amplification transistor 21 are electrically coupled to each other through the shared coupling section 31.

The shared coupling section 31 has a shared trench 311 and includes a coupling conductor 312, as illustrated in FIG. 4.

The shared trench 311 is formed as a stop hole dug down from an upper surface (the second surface) of the pixel separation region 16 toward a side of a lower surface (the first surface) thereof. The stop hole is between the one of the main electrodes 204 of the selection transistor 22 and the one of the main electrodes 204 of the amplification transistor 21. For example, the shared trench 311 is formed to have a depth about the same as a junction depth of the main electrode 204. Here, the shared trench 311 is formed to have a depth shallower than the depth of the second trench of the element separation region 26.

The coupling conductor 312 is embedded in the shared trench 311. One end of the coupling conductor 312 is directly coupled to a side surface of the one of the main electrodes 204 of the amplification transistor 21. Another end of the coupling conductor 312 is directly coupled to a side surface of the one of the main electrodes 204 of the selection transistor 22.

The coupling conductor 312 is formed by a gate electrode material, e.g., a polycrystalline silicon film. The polycrystalline silicon film contains, at high impurity density, an impurity that reduce a resistance value. For example, it is possible to practically use, as the impurity, phosphorus that is an n-type impurity.

The FD conversion gain switching transistor 23 of the pixel circuit 20 is disposed at a position corresponding to the pixel 10C, as illustrated in FIG. 3. The FD conversion gain switching transistor 23 is disposed in the region partitioned by the pixel separation region 16 to allow the direction of the gate length Lg to coincide with the diagonal D1-D1, in a similar manner to the selection transistor 22.

The FD conversion gain switching transistor 23 is disposed on the main surface part of the base 15, as illustrated in FIG. 5. The FD conversion gain switching transistor 23 includes the channel formation region 201, the gate insulating film 202, the gate electrode 203, and the pair of main electrodes 204, in a similar manner to the amplification transistor 21.

The FD region 25 and the base coupling section 27 are disposed at respective positions coinciding with the diagonal D2-D2 and opposed to each other centering around the FD conversion gain switching transistor 23, as illustrated in FIG. 3. Each element separation region 26 is formed between the FD region 25 and the FD conversion gain switching transistor 23 and between the base coupling section 27 and the FD conversion gain switching transistor 23.

The FD conversion gain switching transistor 23 is formed in a shape in line symmetry with the amplification transistor 21 centering around the pixel separation region 16 extending in the arrow-X direction, in a plan view.

Further, the reset transistor 24 of the pixel circuit 20 is disposed at a position corresponding to the pixel 10D. The reset transistor 24 is disposed in the region partitioned by the pixel separation region 16 to allow the direction of the gate length Lg to coincide with the diagonal D2-D2, in a similar manner to the amplification transistor 21.

The reset transistor 24 is disposed on the main surface part of the base 15, as illustrated in FIG. 5. The reset transistor 24 includes the channel formation region 201, the gate insulating film 202, the gate electrode 203, and the pair of main electrodes 204, in a similar manner to the amplification transistor 21.

The FD region 25 and the base coupling section 27 are disposed at respective positions coinciding with the diagonal D1-D1 and opposed to each other centering around the reset transistor 24, as illustrated in FIG. 3. Each element separation region 26 is formed between the FD region 25 and the reset transistor 24 and between the base coupling section 27 and the reset transistor 24.

The reset transistor 24 is formed in a shape in line symmetry with the FD conversion gain switching transistor 23 centering around the pixel separation region 16 extending in the arrow-Y direction, in a plan view. This allows one of the main electrodes 204 of the reset transistor 24 to be disposed at a position with respect to one of the main electrodes 204 of the FD conversion gain switching transistor 23 with the pixel separation region 16 interposed therebetween in the arrow-X direction. The one of the main electrodes (an input electrode or a drain electrode) 204 of the reset transistor 24 and the one of the main electrodes (an output electrode or a source electrode) 204 of the FD conversion gain switching transistor 23 are electrically coupled to each other through the shared coupling section 31.

Further, the respective FD regions 25 disposed in the pixel 10A, the pixel 10B, the pixel 10C, and the pixel 10D are electrically coupled to each other through the shared coupling section 32 having a vertical cross-sectional structure similar to that of the shared coupling section 31, as illustrated in FIGS. 3 and 5.

The shared coupling section 32 has a shared trench 321 having the same configuration as the shared trench 311, and includes a coupling conductor 322 having the same configuration as the coupling conductor 312. The coupling conductor 322 is directly coupled to a side surface of the FD region 25.

Further, the base coupling section 27 disposed in the pixel 10A is electrically coupled through the shared coupling section 33 to the base coupling sections 27 of a total of three other pixels 10 adjacent thereto in the arrow-X direction and the arrow-Y direction, as illustrated in FIGS. 3 and 5. Similarly, each of the base coupling section 27 disposed in the pixel 10B, the base coupling section 27 disposed in the pixel 10C, and the base coupling section 27 disposed in the pixel 10D is electrically coupled through the shared coupling section 33 to the base coupling sections 27 of other adjacent pixels 10 therearound.

The shared coupling section 33 has a shared trench 331 having the same configuration as the shared trench 311, and includes a coupling conductor 332 having the same configuration as the coupling conductor 312. The coupling conductor 332 is directly coupled to a side surface of the base coupling section 27.

The wiring 7 is disposed in an upper layer of the amplification transistor 21 and the like of the pixel circuit 20 with an interlayer insulating film 6 interposed therebetween. The wiring 7 is coupled to the gate electrode 203, the main electrodes 204, the shared coupling section 31, the shared coupling section 32, the shared coupling section 33, and the like through the coupling hole 6H formed in the interlayer insulating film 6. For example, copper wiring is used as the wiring 7.

### [Manufacturing Method of Solid-State Imaging Device 1]

FIGS. 6 to 11 illustrate an example of a manufacturing method of the solid-state imaging device 1 for each of steps.

First, the first trench 161 is formed in a formation region of the pixel separation region 16 of the base 15, and the first embedded member 162 embedded in the first trench 161 is subsequently formed (see FIG. 6). Formation of the first trench 161 and the first embedded member 162 allows the pixel separation region 16 to be substantially formed.

The first trench 161 is formed by removing a portion of the base 15 using, for example, an unillustrated mask. For example, a silicon nitride film is used for the mask. For example, anisotropic etching such as reactive ion etching (RIE: Reactive Ion Etching) is used to remove the base 15.

The second trench 261 is formed, and the second embedded member 262 embedded in the second trench 261 is subsequently formed, in formation regions of the pixel separation region 16 and the element separation region 26 of the base 15, as illustrated in FIG. 6.

A portion of the first embedded member 162 is removed by the second trench 261, and the second embedded member 262 is embedded in the second trench 261, in the formation region of the pixel separation region 16. That is, formation of the first trench 161, the first embedded member 162, the second trench 261, and the second embedded member 262 allows for completion of the pixel separation region 16.

Meanwhile, a portion of the base 15 is removed by the second trench 261, and the second embedded member 262 is embedded in the second trench 261, in the formation region of the element separation region 26. This completes the element separation region 26.

The second trench 261 is formed by removing a portion of the first embedded member 162 and the base 15 using a mask 35. For example, a silicon nitride film is used for the mask 35. For example, anisotropic etching is used to remove the base 15.

The shared trench 311 is formed in a portion of the pixel separation region 16 in a formation region of the shared coupling section 31, as illustrated in FIG. 7. The shared trench 331 is formed in a portion of the pixel separation region 16 in a formation region of the shared coupling section 33 through the same manufacturing step. It is to be noted that, although illustration is omitted, the shared trench 321 is also formed in a portion of the pixel separation region 16 in a formation region of the shared coupling section 32.

Each of the shared trench 311, the shared trench 321, and the shared trench 331 is formed by removing the portion of the pixel separation region 16 (here, a portion of the second embedded member 262) using a mask 36 formed on the mask 35. For example, a photoresist film is used for the mask 36. For example, anisotropic etching is used to remove the pixel separation region 16.

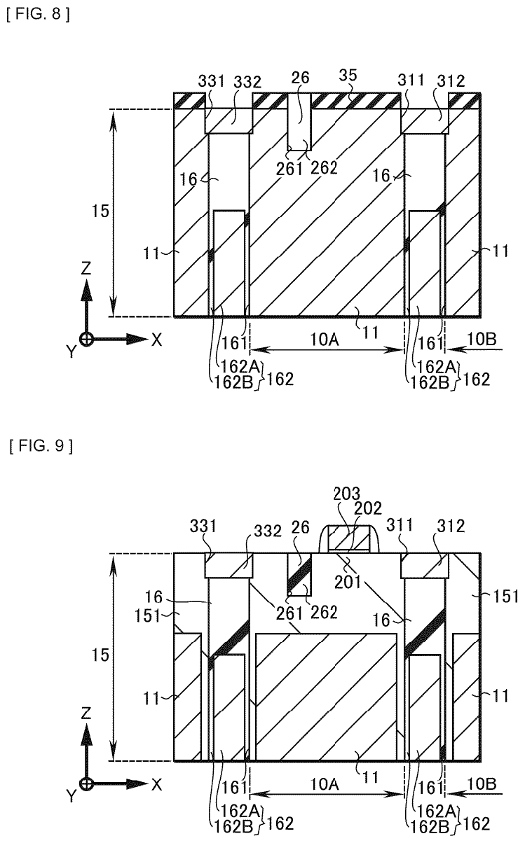

The coupling conductor 312 embedded in the shared trench 311 is formed, as illustrated in FIG. 8. Each of the coupling conductor 322 embedded in the shared trench 321 and the coupling conductor 332 embedded in the shared trench 331 is formed through the same step as the step of forming the coupling conductor 312.

Each of the coupling conductor 312, the coupling conductor 322, and the coupling conductor 332 is formed by a polycrystalline silicon film using, for example, a chemical vapor deposition (CVD: Chemical Vaper Deposition) method. An excess polycrystalline silicon film is removed through, for example, overall etching.

Thereafter, each of the mask 36 and the mask 35 is removed.

Next, the p-type semiconductor region 151 serving as the p-type well region is formed on a side of a main surface (the second surface) of the base 15 (see FIG. 9). The p-type semiconductor region 151 is used as the channel formation region 201 of the transistor 200 in the main surface part of the base 15.

Each of the gate insulating film 202 and the gate electrode 203 is sequentially formed on the p-type semiconductor region 151 in a formation region of the transistor 200, as illustrated in FIG. 9.

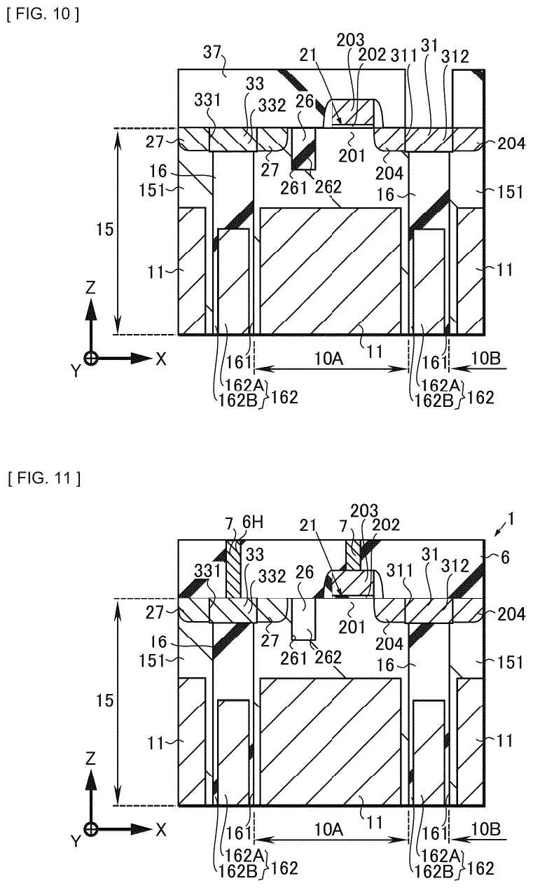

Next, the base coupling section 27 and the shared coupling section 33 are formed (see FIG. 10). The base coupling section 27 is formed by introducing a p-type impurity into the main surface part of the base 15 using an unillustrated mask. Here, the shared coupling section 33 is formed by introducing a p-type impurity into at least the coupling conductor 332 using an unillustrated mask in the same step as the step of forming the base coupling section 27. For example, a photoresist film is used for the mask. An ion implantation method is used to introduce the p-type impurity.

It is to be noted that the p-type impurity may be introduced through a solid phase diffusion method.

The main electrode 204 is formed in the formation region of the transistor 200 (see FIG. 10). The main electrode 204 is formed by introducing an n-type impurity into the main surface part of the base 15 using an unillustrated mask. For example, a photoresist film is used for the mask. For example, an ion implantation method is used to introduce the n-type impurity.

Formation of the main electrodes 204 allows for formation of the amplification transistor 21, the selection transistor 22, the FD conversion gain switching transistor 23, and the reset transistor 24 constructing the pixel circuit 20.

Further, the FD region 25 is formed in the same step as the step of forming the main electrodes 204 (see FIGS. 2, 3, and 5).

The shared coupling section 31 is formed, as illustrated in FIG. 10. The shared coupling section 31 is formed by introducing an n-type impurity into at least the coupling conductor 312 using a mask 37. For example, a photoresist film is used for the mask 37. An ion implantation method is used to introduce the n-type impurity. Further, although not illustrated, the shared coupling section 32 that couples the FD regions 25 to each other is formed in the same step as the step of forming the shared coupling section 31.

Thereafter, the mask 37 is removed.

It is to be noted that the n-type impurity may be introduced through a solid phase diffusion method.

The interlayer insulating film 6 is formed to cover each of the transistor 200, the shared coupling section 31, the shared coupling section 32, and the shared coupling section 33 (see FIG. 11). Subsequently, the coupling hole 6H is formed in the interlayer insulating film 6.

The wiring 7 is formed in the interlayer insulating film 6, as illustrated in FIG. 11. The wiring 7 is coupled to each of regions through the coupling hole 6H.

When the series of steps ends, the solid-state imaging device 1 according to the first embodiment is completed, and the manufacturing method ends.

It is to be noted that the shared coupling section 31 may be formed by introducing an impurity during formation of the coupling conductor 312. Each of the shared coupling section 32 and the shared coupling section 33 may be formed through a method similar to the formation method of the shared coupling section 31.

### [Workings and Effects]

The solid-state imaging device 1 according to the first embodiment includes the pixel (a first pixel) 10A, the pixel (a second pixel) 10B, the transfer transistor (the first transistor) 21, the selection transistor (the second transistor) 22, and the pixel separation region 16, as illustrated in FIGS. 3 and 4.

The pixel 10A includes the photoelectric conversion element (a first photoelectric conversion element) 11 that is disposed on the side of the first surface of the base 15 and that converts light into electric charge. The first surface of the base 15 is the light incident side. The pixel 10B is adjacent to the pixel 10A. The pixel 10B includes the photoelectric conversion element (a second photoelectric conversion element) 11 that is disposed on the side of the first surface of the base 15 and that converts light into electric charge.

The amplification transistor 21 is disposed at the position corresponding to the pixel 10A on the side of the second surface of the base 15, and processes the converted electric charge. The side of the second surface is a side opposite to the first surface. The amplification transistor 21 includes the pair of main electrodes 204. The selection transistor 22 is disposed at the position corresponding to the pixel 10B on the side of the second surface of the base 15, and processes the converted electric charge. The transfer transistor 22 includes the pair of main electrodes 204.

The pixel separation region 16 is disposed between the photoelectric conversion element (the first photoelectric conversion element) 11 and the amplification transistor 21 and between the photoelectric conversion element (the second photoelectric conversion element) 11 and the selection transistor 22. The pixel separation region 16 electrically and optically separates the photoelectric conversion element (the first photoelectric conversion element) 11 and the amplification transistor 21 from each other and electrically and optically separates the photoelectric conversion element (the second photoelectric conversion element) 11 and the selection transistor 22 from each other.

In addition, the solid-state imaging device 1 further includes the shared coupling section 31. The one end of the shared coupling section 31 is electrically coupled directly to the one of the main electrodes 204 of the amplification transistor 21. The other end of the shared coupling section 31 is electrically coupled, across the pixel separation region 16, directly to the one of the main electrodes 204 of the selection transistor 22.

Such a configuration makes it possible to electrically couple to each other the main electrode 204 of the amplification transistor 21 and the main electrode 204 of the transfer transistor 200 without forming a coupling hole and wiring over the pixel separation region 16. This results in effectively no area that is on the main surface of the base 15 and couples the main electrodes 204 to each other. This makes it possible to secure an area sufficient to dispose the amplification transistor 21 in the pixel 10A and the selection transistor 22 in the pixel 10B.

In addition, for example, the area sufficient to dispose the amplification transistor 21 is secured in the pixel 10A, thus making it possible to increase the dimension of the gate length Lg and the dimension of the gate width Wg of the amplification transistor 21. This enables the amplification transistor 21 having excellent noise resistance to be constructed, thus making it possible to improve electrical reliability of the solid-state imaging device 1. The selection transistor 22 also enables achievement of similar workings and effects.

Moreover, in the solid-state imaging device 1, the one end of the shared coupling section 31 is directly coupled to the side surface of the one of the main electrodes 204 of the amplification transistor 21, and the other end of the shared coupling section 31 is directly coupled to the side surface of the one of the main electrodes 204 of the selection transistor, as illustrated in FIG. 4. That is, an area that couples the shared coupling section 31 and the main electrode 204 to each other is secured in the arrow-Z direction, and is substantially not necessary on the main surface of the base 15.

Therefore, it is possible to secure the area sufficient to dispose the amplification transistor 21 in the pixel 10A. Similarly, it is possible to secure the area sufficient to dispose the selection transistor 22 in the pixel 10B.

Further, in the solid-state imaging device 1, the shared coupling section 31 is embedded in the shared trench 311 formed from the second surface of the pixel separation region 16 toward the first surface thereof, as illustrated in FIG. 4. That is, the shared coupling section 31 is formed as a configuration in which the coupling conductor 312 is disposed in the shared trench 311.

This enables the one end of the shared coupling section 31 to be directly coupled to the side surface of the one of the main electrodes 204 of the amplification transistor 21. In addition, it is possible to directly couple the other end of the shared coupling section 31 to the side surface of the one of the main electrodes 204 of the selection transistor.

Furthermore, in the solid-state imaging device 1, the shared coupling section 31 is formed to intersect the pixel separation region 16 on the second surface of the base 15, as illustrated in FIG. 3. The pixel separation region 16 has the first trench 161 having a depth direction in the thickness direction of the base 15, and includes the first embedded member 162 embedded in the first trench 161. The shared coupling section 31 includes a gate electrode material.

Meanwhile, each of the amplification transistor 21 and the selection transistor 22 is surrounded by the element separation region 26 having the second trench 261 and including the second embedded member 262, and is electrically separated from another region. The second trench 261 is formed from the second surface of the base 15 toward the side of the first surface thereof, and has a depth shallower than that of the first trench 161. The second embedded member 262 is embedded in the second trench 261.

In addition, in the solid-state imaging device 1, the direction of the gate length Lg of each of the amplification transistor 21 and the selection transistor 22 is oblique to the extending direction of the pixel separation region 16, as illustrated in FIG. 3. This increases each of the gate length Lg and the gate width Wg of each of the amplification transistor 21 and the selection transistor 22, as compared with a case where the direction of the gate length Lg coincides with the extending direction of the pixel separation region 16. This makes it possible to improve noise resistance performance, and improve an electrical property, in each of the amplification transistor 21 and the selection transistor 22.

In particular, in the solid-state imaging device 1, the direction of the gate length Lg of each of the amplification transistor 21 and the selection transistor 22 is formed at an angle of 45 degrees with respect to the extending direction of the pixel separation region 16. This allows each of the gate length Lg and the gate width Wg of each of the amplification transistor 21 and the selection transistor 22 to be the largest.

Moreover, in the solid-state imaging device 1, at least one of the FD region 25, the vertical gate electrode 205, or the base coupling section 27 is disposed in the direction of the gate width Wg of each of the amplification transistor 21 and the selection transistor 22, as illustrated in FIG. 3.

The FD region 25 transfers the electric charge converted from the light by the photoelectric conversion element 11.

The vertical gate electrode 205 is formed as a control electrode of the transfer transistor 200.

The base coupling section 27 supplies the base 15 with a voltage.

In addition, at least one of the FD region 25, the vertical gate electrode 205, or the base coupling section 27 is disposed with respect to the amplification transistor 21 or the selection transistor 22 with the element separation region 26 interposed therebetween.

Therefore, in a region corresponding to the pixel 10A, at least one of the FD region 25, the vertical gate electrode 205, or the base coupling section 27 is disposed in an unoccupied space other than a region where the amplification transistor 21 is disposed. This makes it possible to improve layout efficiency. Similarly, in a region corresponding to the pixel 10B, at least one of the FD region 25, the vertical gate electrode 205, or the base coupling section 27 is disposed in an unoccupied space other than a region where the selection transistor 22 is disposed. This makes it possible to improve the layout efficiency.

Further, in the solid-state imaging device 1, the amplification transistor 21 and the selection transistor 22 construct the pixel circuit 20 that processes the converted electric charge, as illustrated in FIG. 1. This enables achievement of the solid-state imaging device 1 that makes it possible to improve the electrical reliability while securing the area sufficient to dispose the amplification transistor 21 and the selection transistor 22.

Furthermore, the solid-state imaging device 1 includes the pixel (a third pixel) 10C, the pixel (a fourth pixel) 10D, the FD conversion gain switching transistor (the third transistor) 23, the reset transistor (the fourth transistor) 24, and the pixel separation region 16, as illustrated in FIG. 3.

The pixel 10C includes the photoelectric conversion element (a third photoelectric conversion element) 11 that is disposed on the side of the first surface of the base 15 and that converts light into electric charge. The side of the first surface is the light incident side. The pixel 10D is adjacent to the pixel 10C. The pixel 10D includes the photoelectric conversion element (a fourth photoelectric conversion element) 11 that is disposed on the side of the first surface of the base 15 and that converts light into electric charge.

The FD conversion gain switching transistor 23 is disposed at the position corresponding to the pixel 10C on the side of the second surface of the base 15, and processes the converted electric charge. The side of the second surface is the side opposite to the first surface. The FD conversion gain switching transistor 23 includes the pair of main electrodes 204. The reset transistor 24 is disposed at the position corresponding to the pixel 10D on the side of the second surface of the base 15, and processes the converted electric charge. The reset transistor 24 includes the pair of main electrodes 204.

The pixel separation region 16 is disposed between the photoelectric conversion element (the third photoelectric conversion element) 11 and the FD conversion gain switching transistor 23 and between the photoelectric conversion element (the fourth photoelectric conversion element) 11 and the reset transistor 24. The pixel separation region 16 electrically and optically separates the photoelectric conversion element (the third photoelectric conversion element) 11 and the FD conversion gain switching transistor 23 from each other and electrically and optically separates the photoelectric conversion element (the fourth photoelectric conversion element) 11 and the reset transistor 24 from each other.

In addition, the solid-state imaging device 1 further includes the shared coupling section 31. The one end of the shared coupling section 31 is electrically coupled directly to the one of the main electrodes 204 of the FD conversion gain switching transistor 23. The other end of the shared coupling section 31 is electrically coupled, across the pixel separation region 16, directly to the one of the main electrodes 204 of the reset transistor 24.

Such a configuration makes it possible to electrically couple to each other the main electrode 204 of the FD conversion gain switching transistor 23 and the main electrode 204 of the reset transistor 24 without forming the coupling hole and the wiring over the pixel separation region 16. This results in effectively no area that is on the main surface of the base 15 and couples the main electrodes 204 to each other. This makes it possible to secure an area sufficient to dispose the FD conversion gain switching transistor 23 in the pixel 10C and the reset transistor 24 in the pixel 10D.

In addition, for example, the area sufficient to dispose the FD conversion gain switching transistor 23 is secured in the pixel 10C, thus making it possible to increase the dimension of the gate length Lg and the dimension of the gate width Wg of the FD conversion gain switching transistor 23. This enables the FD conversion gain switching transistor 23 having excellent noise resistance to be constructed, thus making it possible to improve the electrical reliability of the solid-state imaging device 1. The reset transistor 24 also enables achievement of similar workings and effects.

That is, the solid-state imaging device 1 makes it possible to efficiently secure the area sufficient to dispose each of the amplification transistor 21, the selection transistor 22, the FD conversion gain switching transistor 23, and the reset transistor 24 constructing the pixel circuit 20. Moreover, it is possible to improve the electrical reliability of the solid-state imaging device 1. Each of the FD conversion gain switching transistor 23 and the reset transistor 24 also similarly achieves the workings and effects achievable by each of the amplification transistor 21 and the selection transistor 22 on the basis of the shared coupling section 31.

In addition, in the solid-state imaging device 1, the pixel (the first pixel) 10A and the pixel (the second pixel) 10B are arranged to be adjacent to each other in the arrow-X direction serving as a first direction, as illustrated in FIG. 3. The pixel (the third pixel) 10C and the pixel (the fourth pixel) 10D are arranged to be adjacent to the pixel (the first pixel) 10A and the pixel (the second pixel) 10B in the arrow-Y direction intersecting the arrow-X direction and serving as a second direction, and to be adjacent to each other in the arrow-X direction. Moreover, a planar shape of the amplification transistor 21 and the selection transistor 22 is a shape formed in line symmetry with respect to the pixel separation region 16 disposed between both the amplification transistor 21 and the selection transistor 22.

Similarly, a planar shape of the FD conversion gain switching transistor 23 and the reset transistor 24 is a shape formed in line symmetry with respect to the pixel separation region 16 disposed between both the FD conversion gain switching transistor 23 and the reset transistor 24.

Such a configuration makes it possible to improve efficiency of a disposition layout of the transistor 200 with respect to the pixel 10, and possible to couple to each other the transistors 200 by the shortest distance with the shared coupling section 31 interposed therebetween.

It is to be noted that the shared coupling section 32 that couples the FD regions 25 to each other and the shared coupling section 33 that couples the base coupling sections 27 to each other also make it possible to achieve workings and effects similar to the workings and effects achievable by the shared coupling section 31.

### 2. Second Embodiment

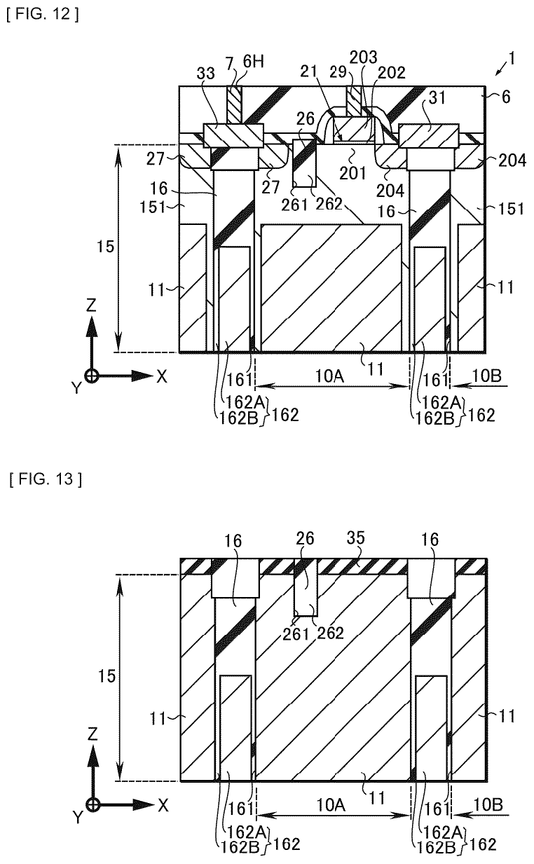

Description is given of the solid-state imaging device 1 according to the second embodiment of the present disclosure with reference to FIGS. 12 to 17. It is to be noted that, in the second embodiment and subsequent embodiments, components the same as or components substantially the same as the components of the solid-state imaging device 1 according to the first embodiment are denoted by the same reference numerals, and redundant description is omitted.

### [Configuration of Solid-State Imaging Device 1]

FIG. 12 illustrates an example of a vertical cross-sectional configuration of a portion of the pixels 10 and the pixel circuit 20 constructing the solid-state imaging device 1.

In the solid-state imaging device 1 according to the second embodiment, the one end of the shared coupling section 31 is directly coupled to a surface of the one of the main electrodes 204 of the amplification transistor 21. The other end of the shared coupling section 31 is directly coupled, across the pixel separation region 16, to a surface of the one of the main electrodes 204 of the selection transistor 22.

The shared coupling section 31 is formed by the coupling conductor 311 itself of the shared coupling section 31 of the solid-state imaging device 1 according to the first embodiment. The shared trench 311 for which a portion of the pixel separation region 16 is dug down is not formed. To give detailed description, the shared coupling section 31 is formed by, for example, a polycrystalline silicon film as a gate electrode material. An n-type impurity of the same electrically conductive type as the main electrode 204 is introduced into the polycrystalline silicon film.

Here, although illustration is omitted, the one of the main electrodes 204 of the FD conversion gain switching transistor 23 and the one of the main electrodes 204 of the reset transistor 24 are similarly coupled to each other through the shared coupling section 31 (see FIG. 3). In addition, the FD regions 25 of the plurality of pixels 10 adjacent to each other are coupled to each other through the shared coupling section 32 having a similar configuration (see FIG. 3).

The base coupling sections 27 of the plurality of pixels 10 adjacent to each other are coupled to each other through the shared coupling section 33 having a structure similar to that of the shared coupling section 31 (see FIGS. 3 and 12). The shared coupling section 33 is formed by, for example, a polycrystalline silicon film. A p-type impurity of the same electrically conductive type as the base coupling section 27 is introduced into the polycrystalline silicon film.

Components other than the above-described components are components the same or substantially the same as the components of the solid-state imaging device 1 according to the first embodiment.

### [Manufacturing Method of Solid-State Imaging Device 1]

FIGS. 13 to 17 illustrate an example of the manufacturing method of the solid-state imaging device 1 for each of the steps.

As illustrated in FIG. 13, the pixel separation region 16 and the element separation region 26 are first formed, in a similar manner to the step illustrated in FIG. 6 of the manufacturing method of the solid-state imaging device 1 according to the first embodiment (hereinafter, simply referred to as a “first manufacturing method”). The mask 35 is used to form the element separation region 26, as described in the first manufacturing method.

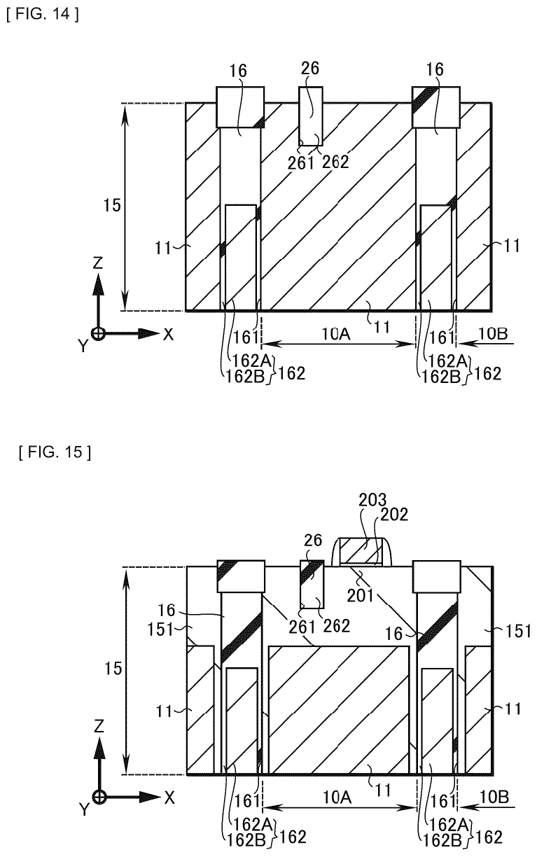

The mask 35 is removed, as illustrated in FIG. 14.

As illustrated in FIG. 15, each of the p-type semiconductor region 151, the gate insulating film 202, and the gate electrode 203 is sequentially formed on the side of the main surface (the second surface) of the base 15, in a similar manner to the step illustrated in FIG. 9 of the first manufacturing method. The p-type semiconductor region 151 serves as the p-type well region.

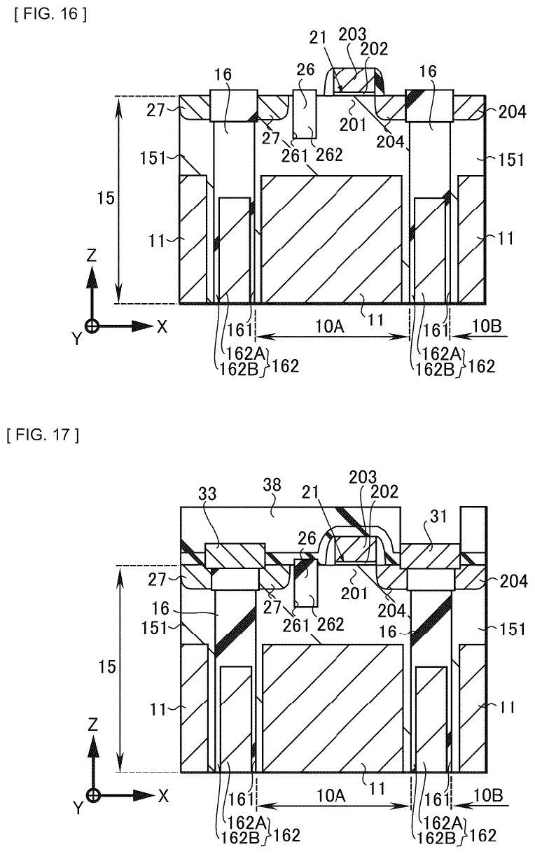

Next, the base coupling section 27 is formed in the main surface part of the p-type semiconductor region 151 in a region partitioned by the pixel separation region 16 and surrounded by the element separation region 26 (see FIG. 16). The base coupling section 27 is formed by a p-type semiconductor region formed to be of the same electrically conductive type as the p-type semiconductor region 151 and having higher impurity density than the p-type semiconductor region 151. Although illustration is omitted, the base coupling section 27 is formed by introducing a p-type impurity using a mask. An ion implantation method is used to introduce the p-type impurity.

The main electrode 204 of the transistor 200 is formed in the region partitioned by the pixel separation region 16 and surrounded by the element separation region, as illustrated in FIG. 16. FIG. 16 illustrates the main electrode 204 of the amplification transistor 21 and the main electrode 204 of the selection transistor 22. The main electrodes 204 are each formed by an n-type semiconductor region formed to be of an electrically conductive type opposite to that of the p-type semiconductor region 151 and having higher impurity density than the p-type semiconductor region 151. The main electrodes 204 are each formed by introducing an n-type impurity using an unillustrated mask. For example, a photoresist film is used for the mask. An ion implantation method is used to introduce the n-type impurity.

Here, the FD region 25, of which illustration is omitted here, is formed in the same step as the step of forming the main electrodes 204.

The shared coupling section 33 is formed across the base coupling sections 27 of the adjacent pixels 10, and the shared coupling section 31 is formed across the main electrodes 204 of the transistors 200 of the adjacent pixels 10, as illustrated in FIG. 17.

Each of the shared coupling section 33 and the shared coupling section 31 is formed by, for example, a polycrystalline silicon film formed in the same step. A p-type impurity is introduced into the shared coupling section 33 using an unillustrated mask. An n-type impurity is introduced into the shared coupling section 31 using a mask 38. For example, a photoresist film is used for the unillustrated mask and the mask 38. For example, an ion implantation method is used to introduce each of the p-type impurity and the n-type impurity.

It is to be noted that, although illustration is omitted, the shared coupling section 32 is formed across the FD regions 25 of the adjacent pixels 10 in the same step as the step of forming the shared coupling section 31.

Thereafter, the mask 38 is removed.

The interlayer insulating film 6 is formed to cover each of the transistor 200, the shared coupling section 31, the shared coupling section 32, and the shared coupling section 33 (see FIG. 12). Subsequently, the coupling hole 6H is formed in the interlayer insulating film 6.

The wiring 7 is formed in the interlayer insulating film 6, as illustrated in FIG. 12. The wiring 7 is coupled to each of the regions through the coupling hole 6H.

When the series of steps ends, the solid-state imaging device 1 according to the second embodiment is completed, and the manufacturing method ends.

It is to be noted that the shared coupling section 31 may be formed by, for example, introducing an impurity during formation of the polycrystalline silicon film. Each of the shared coupling section 32 and the shared coupling section 33 may be formed through a method similar to the formation method of the shared coupling section 31.

### [Workings and Effects]

The solid-state imaging device 1 according to the second embodiment makes it possible to achieve workings and effects similar to the workings and effects achievable by the solid-state imaging device 1 according to the first embodiment.

Further, in the solid-state imaging device 1, the one end of the shared coupling section 31 is directly coupled to the surface of the one of the main electrodes 204 of the amplification transistor (the first transistor) 21, as illustrated in FIG. 12. The other end of the shared coupling section 31 is directly coupled to the surface of the one of the main electrodes 204 of the selection transistor (the second transistor) 22.

Such a configuration makes it possible to electrically couple to each other the main electrode 204 of the amplification transistor 21 and the main electrode 204 of the transfer transistor 200 without forming the coupling hole and the wiring over the pixel separation region 16. The shared coupling section 31 is disposed to overlap the main electrodes 204 in a plan view, making unnecessary an alignment margin dimension of a coupling hole or the like to couple both the shared coupling section 31 and the main electrode 204 to each other. This does not increase the area that is on the main surface of the base 15 and couples the main electrodes 204 to each other. This makes it possible to secure the area sufficient to dispose the amplification transistor 21 in the pixel 10A and the selection transistor 22 in the pixel 10B.

In addition, for example, the area sufficient to dispose the amplification transistor 21 is secured in the pixel 10A, thus making it possible to increase the dimension of the gate length Lg and the dimension of the gate width Wg of the amplification transistor 21. This enables the amplification transistor 21 having excellent noise resistance to be constructed, thus making it possible to improve the electrical reliability of the solid-state imaging device 1. The selection transistor 22 also enables achievement of similar workings and effects.

Furthermore, in the solid-state imaging device 1, the one end of the shared coupling section 31 is directly coupled to a surface of the one of the main electrodes 204 of the FD conversion gain switching transistor (the third transistor) 23 (see FIGS. 1 and 3). The other end of the shared coupling section 31 is directly coupled to a surface of the one of the main electrodes 204 of the reset transistor (the fourth transistor) 24. Therefore, coupling to each other the main electrodes 204 of the FD conversion gain switching transistor 23 and the reset transistor 24 also makes it possible to achieve workings and effects similar to the workings and effects achievable by coupling to each other the main electrodes 204 of the amplification transistor 21 and the selection transistor 22.

It is to be noted that the shared coupling section 32 that couples the FD regions 25 to each other and the shared coupling section 33 that couples the base coupling sections 27 to each other also make it possible to achieve workings and effects similar to the workings and effects achievable by the shared coupling section 31.

### 3. Third Embodiment

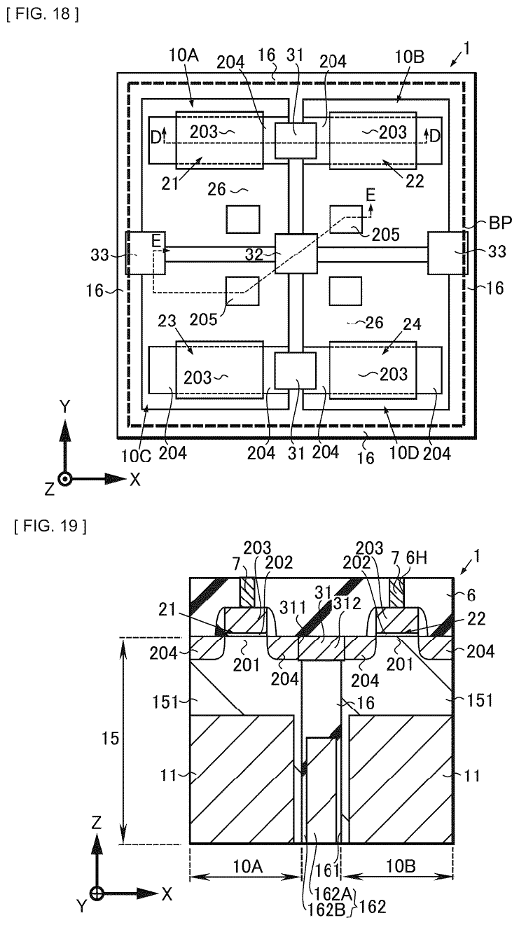

Description is given of the solid-state imaging device 1 according to the third embodiment of the present disclosure with reference to FIGS. 18 to 20.

### [Configuration of Solid-State Imaging Device 1]

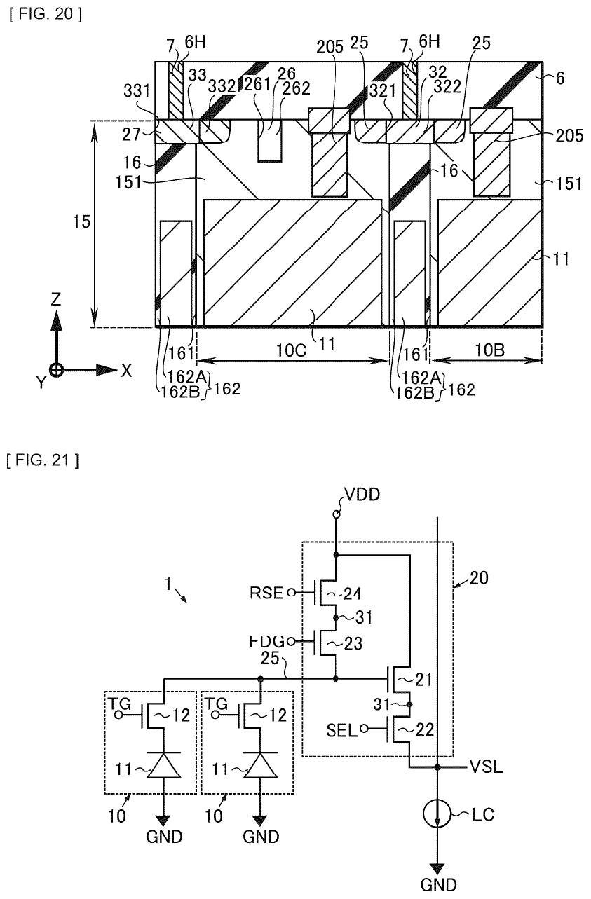

FIG. 18 illustrates an example of a specific planar configuration of the pixels 10 and the pixel circuit 20. FIG. 19 illustrates a vertical cross-sectional configuration of a portion of the pixels 10 and the pixel circuit 20 (a cross-section sectioned along a section line D-D illustrated in FIG. 18). FIG. 20 illustrates a vertical cross-sectional configuration of another portion of the pixels 10 and the pixel circuit 20 (a cross-section sectioned along a section line E-E illustrated in FIG. 18).

In the solid-state imaging device 1 according to the third embodiment, the amplification transistor 21 of the pixel circuit 20 is disposed at the position corresponding to the pixel 10A, as illustrated in FIG. 3. The amplification transistor 21 is disposed in the region partitioned by the pixel separation region 16 to allow the direction of the gate length Lg to coincide with the arrow-X direction. In other words, the amplification transistor 21 is disposed to allow the direction of the gate length Lg to be parallel to the pixel separation region 16 extending in the arrow-X direction.

Each of the FD region 25 and the base coupling section 27 is disposed in the direction of the gate width Wg of the amplification transistor 21. Each element separation region 26 is formed between the FD region 25 and the amplification transistor 21 and between the base coupling section 27 and the amplification transistor 21.

Similarly, the selection transistor 22 of the pixel circuit 20 is disposed at the position corresponding to the pixel 10B. The selection transistor 22 is disposed in the region partitioned by the pixel separation region 16 to allow the direction of the gate length Lg to coincide with the arrow X-direction.

The selection transistor 22 is formed in a shape in line symmetry with the amplification transistor 21 centering around the pixel separation region 16 extending in the arrow-Y direction, in a plan view.

Each of the FD region 25 and the base coupling section 27 is disposed in the direction of the gate width Wg of the selection transistor 22. Each element separation region 26 is formed between the FD region 25 and the selection transistor 22 and between the base coupling section 27 and the selection transistor 22.

The FD conversion gain switching transistor 23 of the pixel circuit 20 is disposed at the position corresponding to the pixel 10C. The FD conversion gain switching transistor 23 is disposed in the region partitioned by the pixel separation region 16 to allow the direction of the gate length Lg to coincide with the arrow-X direction.

The FD conversion gain switching transistor 23 is formed in a shape in line symmetry with the amplification transistor 21 centering around the pixel separation region 16 extending in the arrow-X direction, in a plan view.

Each of the FD region 25 and the base coupling section 27 is disposed in the direction of the gate width Wg of the FD conversion gain switching transistor 23. Each element separation region 26 is formed between the FD region 25 and the FD conversion gain switching transistor 23 and between the base coupling section 27 and the FD conversion gain switching transistor 23.

The reset transistor 24 of the pixel circuit 20 is disposed at the position corresponding to the pixel 10D. The reset transistor 24 is disposed in the region partitioned by the pixel separation region 16 to allow the direction of the gate length Lg to coincide with the arrow-X direction.

The reset transistor 24 is formed in a shape in line symmetry with the FD conversion gain switching transistor 23 centering around the pixel separation region 16 extending in the arrow-Y direction, in a plan view.

Each of the FD region 25 and the base coupling section 27 is disposed in the direction of the gate width Wg of the reset transistor 24. Each element separation region 26 is formed between the FD region 25 and the reset transistor 24 and between the base coupling section 27 and the reset transistor 24.

The one of the main electrodes 204 of the selection transistor 22 and the one of the main electrodes 204 of the amplification transistor 21 are electrically coupled to each other through the shared coupling section 31, as illustrated in FIGS. 3 and 4. The shared coupling section 31 has the same structure as the shared coupling section 31 of the solid-state imaging device 1 according to the first embodiment.

Similarly, the one of the main electrodes 204 of the FD conversion gain switching transistor 23 and the one of the main electrodes 204 of the reset transistor 24 are electrically coupled to each other through the shared coupling section 31.

The FD region 25 disposed in the pixel 10A, the FD region 25 disposed in the pixel 10B, the FD region 25 disposed in the pixel 10C, and the FD region 25 disposed in the pixel 10D are electrically coupled to each other through the shared coupling section 32, as illustrated in FIGS. 3 and 5.

Similarly, the base coupling section 27 disposed in the pixel 10A, the base coupling section 27 disposed in the pixel 10C, and the base coupling sections 27 disposed in unillustrated pixels 10 are electrically coupled to each other through the shared coupling section 33. Further, the base coupling section 27 disposed in the pixel 10B, the base coupling section 27 disposed in the pixel 10D, and the base coupling sections 27 disposed in unillustrated pixels 10 are electrically coupled to each other through the shared coupling section 33.

Components other than the above-described components are components the same or substantially the same as the components of the solid-state imaging device 1 according to the first embodiment.

It is to be noted that the shared coupling section 31 may have the same structure as the shared coupling section 31 of the solid-state imaging device 1 according to the second embodiment. The same applies to each of the shared coupling section 32 and the shared coupling section 33.

### [Workings and Effects]

The solid-state imaging device 1 according to the third embodiment makes it possible to achieve workings and effects similar to the workings and effects achievable by the solid-state imaging device 1 according to the first embodiment or the second embodiment.

### 4. Fourth Embodiment

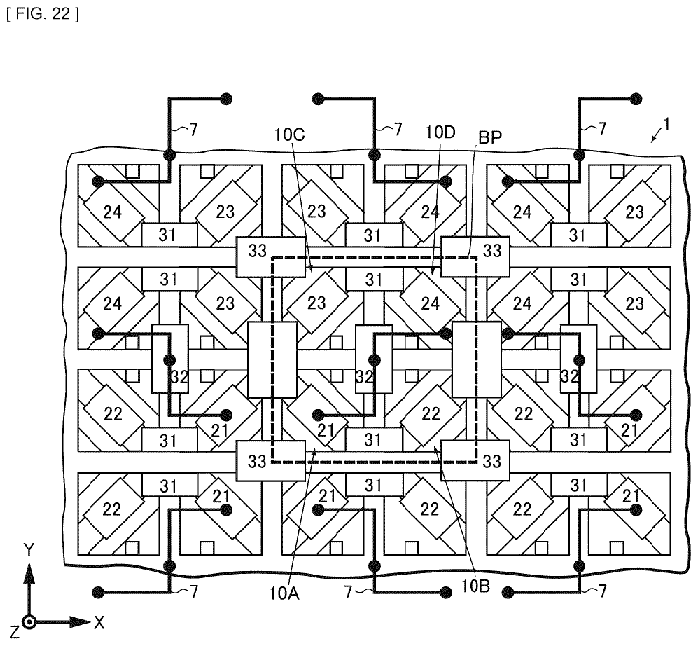

Description is given of the solid-state imaging device 1 according to the fourth embodiment of the present disclosure with reference to FIGS. 21 and 22.

### [Configuration of Solid-State Imaging Device 1]

### (1) Circuit Configuration of Pixel 10 and Pixel Circuit 20 of Solid-State Imaging Device 1

FIG. 21 illustrates an example of a circuit configuration of the pixels 10 and the pixel circuit 20 constructing the solid-state imaging device 1.

The solid-state imaging device 1 according to the second embodiment is a practical application example of the solid-state imaging device 1 according to the first embodiment or the second embodiment. In the solid-state imaging device 1 according to the second embodiment, one pixel circuit 20 is configured for two pixels 10.

### (2) Layout Configuration of Pixel 10 and Pixel Circuit 20

FIG. 22 illustrates an example of a specific planar layout configuration of the pixels 10 and the pixel circuits 20.

In the second embodiment, four pixels, i.e., the pixel 10A, the pixel 10B, the pixel 10C, and the pixel 10D, are configured as a unit pixel BP. The pixel 10A, the pixel 10B, the pixel 10C, and the pixel 10D share the FD region 25. Here, description is given of the planar layout configuration of the pixel circuit 20 by centering around the unit pixel BP of which a periphery is surrounded by a broken line in the drawing.

The amplification transistor 21 is disposed at the position corresponding to the pixel 10A. The amplification transistor 21 is disposed in the region partitioned by the pixel separation region 16 to allow the direction of the gate length Lg to coincide with the diagonal D1-D1 (see the diagonal D1-D1 illustrated in FIG. 3).

The selection transistor 22 is disposed at the position corresponding to the pixel 10B adjacent to the pixel 10A in the arrow-X direction. The selection transistor 22 is disposed in the region partitioned by the pixel separation region 16 to allow the direction of the gate length Lg to coincide with the diagonal D2-D2 (see the diagonal D2-D2 illustrated in FIG. 3).

The selection transistor 22 is formed in a shape in line symmetry with the amplification transistor 21 centering around the pixel separation region 16 extending in the arrow-Y direction, in a plan view. This allows the one of the main electrodes 204 of the selection transistor 22 to be disposed at the position with respect to the one of the main electrodes 204 of the amplification transistor 21 with the pixel separation region 16 interposed therebetween in the arrow-X direction. The one of the main electrodes 204 of the selection transistor 22 and the one of the main electrodes 204 of the amplification transistor 21 are electrically coupled to each other through the shared coupling section 31.

The reset transistor 24 is disposed at the position corresponding to the pixel 10D adjacent to the pixel 10A in the arrow-Y direction. The reset transistor 24 is disposed in the region partitioned by the pixel separation region 16 to allow the direction of the gate length Lg to coincide with the diagonal D2-D2 (see the diagonal D2-D2 illustrated in FIG. 3).

The reset transistor 24 is formed in a shape in line symmetry with the amplification transistor 21 centering around the pixel separation region 16 extending in the arrow-X direction, in a plan view.

The FD conversion gain switching transistor 23 is disposed at the position corresponding to the pixel 10C adjacent to the pixel 10D in the arrow-X direction. The FD conversion gain switching transistor 23 is disposed in the region partitioned by the pixel separation region 16 to allow the direction of the gate length Lg to coincide with the diagonal D1-D1 (see the diagonal D1-D1 illustrated in FIG. 3).

The FD conversion gain switching transistor 23 is formed in a shape in line symmetry with the reset transistor 24 centering around the pixel separation region 16 extending in the arrow-Y direction, in a plan view. This allows the one of the main electrodes 204 of the reset transistor 24 to be disposed at the position with respect to the one of the main electrodes 204 of the FD conversion gain switching transistor 23 with the pixel separation region 16 interposed therebetween in the arrow-X direction. The one of the main electrodes 204 of the reset transistor 24 and the one of the main electrodes 204 of the FD conversion gain switching transistor 23 are electrically coupled to each other through the shared coupling section 31.

In addition, the pixel 10A and the pixel 10B of another pixel unit BP are disposed at a position adjacent to the pixel 10A and the pixel 10B on an opposite side in the arrow-Y direction. The pixels 10A of the respective pixel units BP are formed in a shape in line symmetry with each other, and the pixels 10B of the respective pixel units BP are formed in a shape in line symmetry with each other, centering around the pixel separation region 16 extending in the arrow-X direction.

Similarly, the pixel 10D and the pixel 10C of another pixel unit BP are disposed at a position adjacent to the pixel 10D and the pixel 10C in the arrow-Y direction. The pixels 10D of the respective pixel units BP are formed in a shape in line symmetry with each other, and the pixels 10C of the respective pixel units BP are formed in a shape in line symmetry with each other, centering around the pixel separation region 16 extending in the arrow-X direction.

Meanwhile, the pixel 10A and the pixel 10D of another pixel unit BP are disposed at a position adjacent to the pixel 10A and the pixel 10D on an opposite side in the arrow-X direction. The pixels 10A of the respective pixel units BP are formed in a shape in line symmetry with each other, and the pixels 10D of the respective pixel units BP are formed in a shape in line symmetry with each other, centering around the pixel separation region 16 extending in the arrow-Y direction.

Similarly, the pixel 10B and the pixel 10C of another pixel unit BP are disposed at a position adjacent to the pixel 10B and the pixel 10C in the arrow-X direction. The pixels 10B of the respective pixel units BP are formed in a shape in line symmetry with each other, and the pixels 10C of the respective pixel units BP are formed in a shape in line symmetry with each other, centering around the pixel separation region 16 extending in the arrow-Y direction.

In the pixel circuit 20 having such a configuration, the respective FD regions 25 are disposed to be concentrated at a middle part of the four pixels, i.e., the pixel 10A, the pixel 10B, the pixel 10C, and the pixel 10D, in the unit pixel BP. The FD regions 25 are electrically coupled to each other through the shared coupling section 32.

Moreover, the FD region 25 is electrically coupled through the wiring 7 to each of another one of the main electrodes 204 of the FD conversion gain switching transistor 23 and the gate electrode 203 of the amplification transistor 21.

Moreover, the pixel 10A of the unit pixel BP is adjacent to the pixels 10A of a total of three other unit pixels BP on the opposite side in the arrow-X direction and on the opposite side in the arrow-Y direction. This allows the base coupling sections 27 to be disposed to be concentrated at a middle part of the four adjacent pixels 10A. The base coupling sections 27 are electrically coupled to each other through the shared coupling section 33.

Similarly, the pixel 10B of the unit pixel BP is adjacent to the pixels 10B of a total of three other unit pixels BP on the opposite sides in the arrow-X direction and in the arrow-Y direction. The base coupling sections 27 are disposed to be concentrated at a middle part of the four adjacent pixels 10B. The base coupling sections 27 are electrically coupled to each other through the shared coupling section 33.

The pixel 10C of the unit pixel BP is adjacent to the pixels 10C of a total of three other unit pixels BP in the arrow-X direction and the arrow-Y direction. The base coupling sections 27 are disposed to be concentrated at a middle part of the four adjacent pixels 10C. The base coupling sections 27 are electrically coupled to each other through the shared coupling section 33.

In addition, the pixel 10D of the unit pixel BP is adjacent to the pixels 10D of a total of three other unit pixels BP on the opposite side in the arrow-X direction and in the arrow-Y direction. The base coupling sections 27 are disposed to be concentrated at a middle part of the four adjacent pixels 10D. The base coupling sections 27 are electrically coupled to each other through the shared coupling section 33.

Components other than the above-described components are components the same or substantially the same as the components of the solid-state imaging device 1 according to the first embodiment or the second embodiment.

### [Workings and Effects]

The solid-state imaging device 1 according to the fourth embodiment makes it possible to achieve workings and effects similar to the workings and effects achievable by the solid-state imaging device 1 according to the first embodiment or the second embodiment.

Further, in the solid-state imaging device 1, the respective FD regions 25 are disposed to be concentrated at the middle part of the four pixels, i.e., the pixel 10A, the pixel 10B, the pixel 10C, and the pixel 10D, as illustrated in FIG. 22. The pixel 10A, the pixel 10B, the pixel 10C, and the pixel 10D configure the unit pixel BP. The FD regions 25 are electrically coupled to each other through the shared coupling section 32. This makes it possible to secure the area sufficient to dispose the transistor 200 in the pixel 10.

Furthermore, in the solid-state imaging device 1, the respective base coupling sections 27 are disposed to be concentrated at the middle part of a total of four pixels 10 in which the same transistors 200 are disposed, as illustrated in FIG. 22. The pixels 10 are adjacent to one pixel configuring the unit pixel BP. The base coupling sections 27 are electrically coupled to each other through the shared coupling section 33. This makes it possible to secure the area sufficient to dispose the transistor 200 in the pixel 10.

### 5. Fifth Embodiment

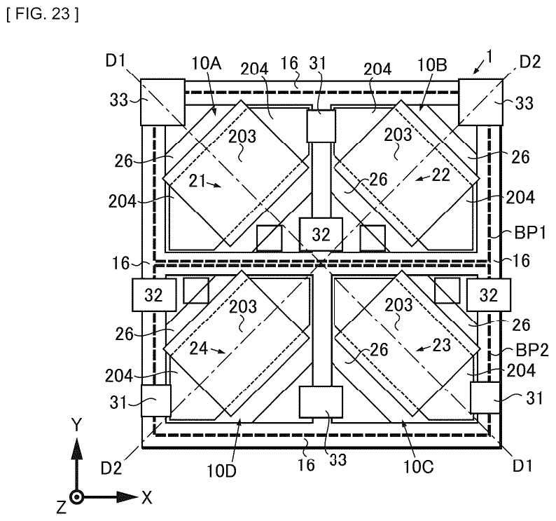

Description is given of the solid-state imaging device 1 according to the fifth embodiment of the present disclosure with reference to FIG. 23.

### [Configuration of Solid-State Imaging Device 1]

FIG. 23 illustrates an example of a specific planar configuration of the pixels 10 and the pixel circuit 20.

In the solid-state imaging device 1 according to the fifth embodiment, two pixels, i.e., the pixel 10A and the pixel 10B, configure a unit pixel BP1. The pixel 10A and the pixel 10B are adjacent to each other in the arrow X-direction, and share the FD region 25. In addition, two pixels, i.e., the pixel 10C and the pixel 10D, configure a unit pixel BP2. The pixel 10C and the pixel 10D are adjacent to the pixel 10A and the pixel 10B in the arrow-Y direction, and are adjacent to each other in the arrow-X direction.

The amplification transistor 21 is disposed at the position corresponding to the pixel 10A, in a similar manner to the solid-state imaging device 1 according to the first embodiment. The selection transistor 22 is disposed at the position corresponding to the pixel 10B. The one of the main electrodes 204 of the amplification transistor 21 and the one of the main electrodes 204 of the selection transistor 22 are electrically coupled to each other through the shared coupling section 31.

The respective FD regions 25 of the pixel 10A and the pixel 10B are electrically coupled to each other through the shared coupling section 32.

Meanwhile, the base coupling section 27 of the pixel 10A is electrically coupled through the shared coupling section 33 to the base coupling section 27 of the pixel 10 of another unit pixel BP1 adjacent thereto on the opposite side in the arrow-X direction. The base coupling section 27 of the pixel 10B is electrically coupled through the shared coupling section 33 to the base coupling section 27 of the pixel 10 of another unit pixel BP1 adjacent thereto in the arrow-X direction.

In the solid-state imaging device 1 according to the fifth embodiment, disposition positions of the pixel 10C and the pixel 10D are reversed in the arrow-X direction with respect to the disposition positions of the pixel 10C and the pixel 10D, illustrated in FIG. 3, of the solid-state imaging device 1 according to the first embodiment.

The FD conversion gain switching transistor 23 is disposed at the position corresponding to the pixel 10C. The FD conversion gain switching transistor 23 is disposed in the region partitioned by the pixel separation region 16 to allow the direction of the gate length Lg to coincide with the diagonal D1-D1.

The reset transistor 24 is disposed at the position corresponding to the pixel 10D. The reset transistor 24 is disposed in the region partitioned by the pixel separation region 16 to allow the direction of the gate length Lg to coincide with the diagonal D2-D2.

The one of the main electrodes 204 of the FD conversion gain switching transistor 23 is electrically coupled through the shared coupling section 31 to the one of the main electrodes 204 of the reset transistor 24 of the pixel 10D of another unit pixel BP2 adjacent thereto in the arrow-X direction. Similarly, the FD region 25 of the pixel 10C is electrically coupled through the shared coupling section 32 to the FD region 25 of the pixel 10D of the other unit pixel BP2 adjacent thereto in the arrow-X direction.

The one of the main electrodes 204 of the reset transistor 24 is electrically coupled through the shared coupling section 31 to the one of the main electrodes 204 of the FD conversion gain switching transistor 23 of the pixel 10C of another unit pixel BP2 adjacent thereto on the opposite side in the arrow-X direction. Similarly, the FD region 25 of the pixel 10D is electrically coupled through the shared coupling section 32 to the FD region 25 of the pixel 10D of the other unit pixel BP2 adjacent thereto on the opposite side in the arrow-X direction.

In the unit pixel BP2, the respective base coupling sections 27 of the pixel 10C and the pixel 10D are electrically coupled to each other through the shared coupling section 33.

Components other than the above-described components are components the same or substantially the same as the components of the solid-state imaging device 1 according to the first embodiment.

### [Workings and Effects]

The solid-state imaging device 1 according to the fifth embodiment makes it possible to achieve workings and effects similar to the workings and effects achievable by the solid-state imaging device 1 according to the first embodiment or the second embodiment.

Moreover, in the solid-state imaging device 1, each of the shared coupling section 31, the shared coupling section 32, and the shared coupling section 33 is disposed in two pixels 10 adjacent to each other in the arrow-X direction, as illustrated in FIG. 23. In addition, each of the shared coupling section 31, the shared coupling section 32, and the shared coupling section 33 is disposed to be shifted by a distance corresponding to one pixel 10 in the arrow-X direction with respect to the two pixels 10, in two pixels 10 adjacent thereto in the arrow-Y direction.

### 6. Sixth Embodiment

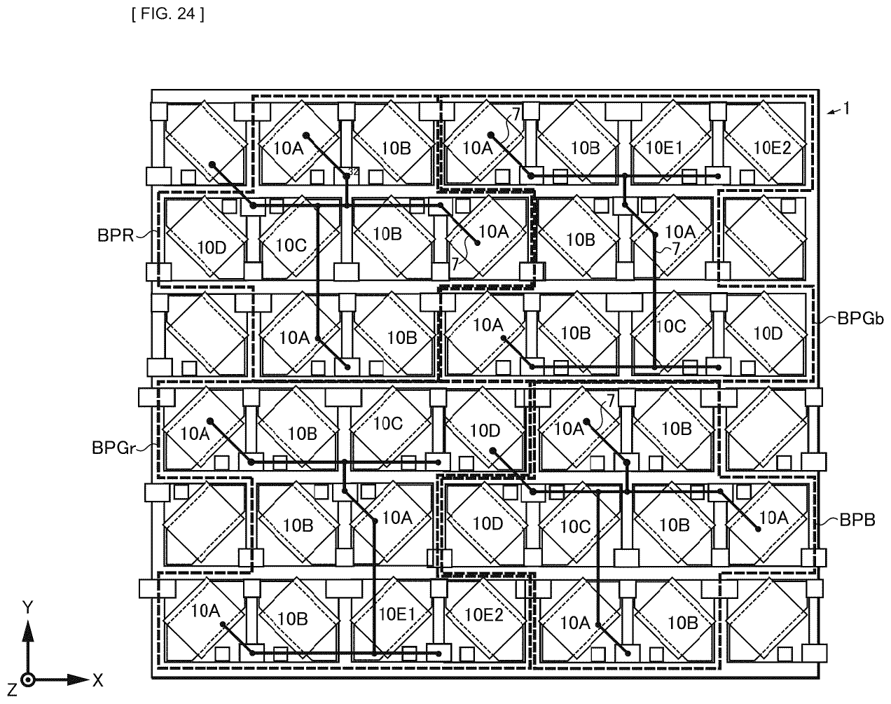

Description is given of the solid-state imaging device 1 according to the sixth embodiment of the present disclosure with reference to FIGS. 24 to 29.

### [Configuration of Solid-State Imaging Device 1]

### (1) Layout Configuration of Pixel 10 and Pixel Circuit 20 of Solid-State Imaging Device 1

FIG. 24 illustrates an example of a specific planar layout configuration of the pixels 10 and the pixel circuits 20.

In the solid-state imaging device 1 according to the sixth embodiment, two pixels, i.e., the pixel 10A and the pixel 10B, configure the unit pixel BP1, in a similar manner to the solid-state imaging device 1 according to the fifth embodiment. The pixel 10A and the pixel 10B are adjacent to each other in the arrow-X direction, and share the FD region 25. In addition, two pixels, i.e., the pixel 10C and the pixel 10D, configure the unit pixel BP2. The pixel 10C and the pixel 10D are adjacent to the pixel 10A and the pixel 10B in the arrow-Y direction, and are adjacent to each other in the arrow-X direction. Here, the unit pixel BP2 is disposed at a position shifted by one pixel 10 in the arrow-X direction with respect to the unit pixel BP1.

### (2) Layout Configuration of Pixel 10, Pixel Circuit 20, and Color Filter 4

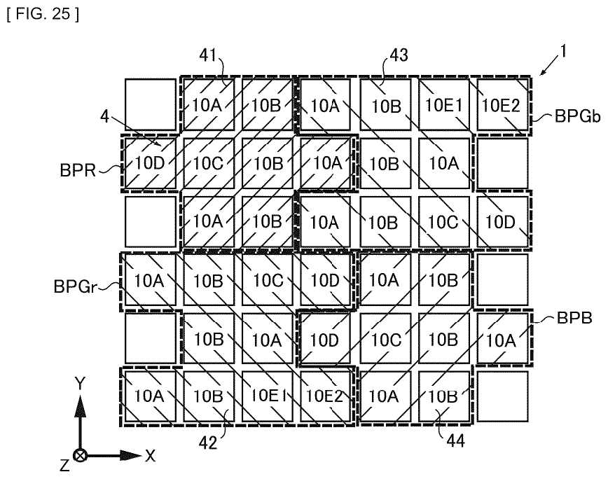

FIG. 25 illustrates an example of a planar layout configuration of a color filter 4 to be disposed at the pixels 10 illustrated in FIG. 24.

The color filter 4 is disposed at the pixels 10. Although description using a vertical cross-section is omitted, the color filter 4 is disposed on the side of the first surface of the base 15.

In the sixth embodiment, the color filter 4 includes a red filter 41, a green filter (red side) 42, a green filter (blue side) 43, and a blue filter 44.

In the color filter 4, each of the red filter 41 and the green filter (blue side) 43 is alternately arranged in the arrow-X direction. Further, the green filter (red side) 42 is arranged to be adjacent to the red filter 41 in the arrow-Y direction and on the side opposite thereto. Furthermore, the blue filter 44 is arranged to be adjacent to the green filter (blue side) 43 in the arrow-Y direction and on the side opposite thereto. That is, each of the green filter (red side) 42 and the blue filter 44 is alternately arranged in the arrow-X direction.

### (3) Planar Layout Configuration of Red Filter 41 and Blue Filter 44

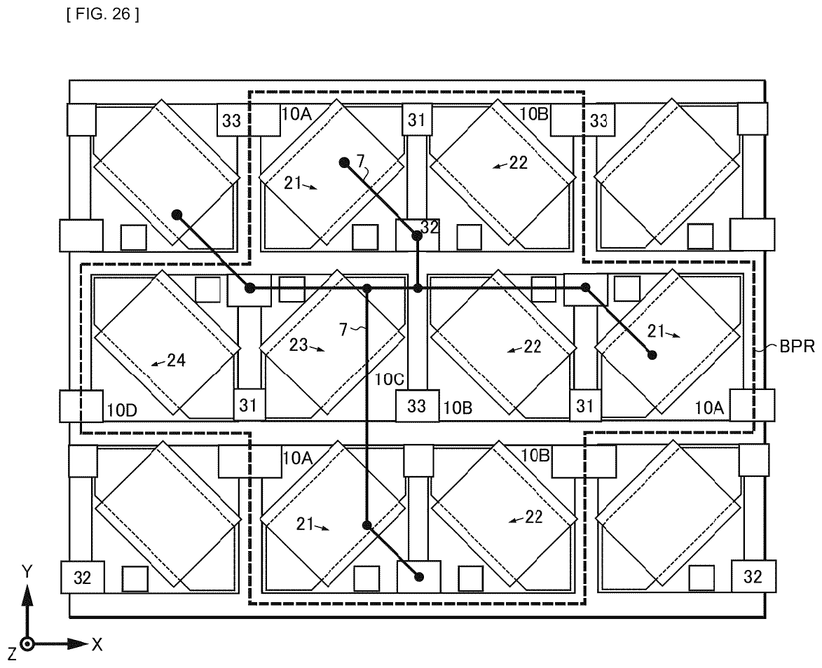

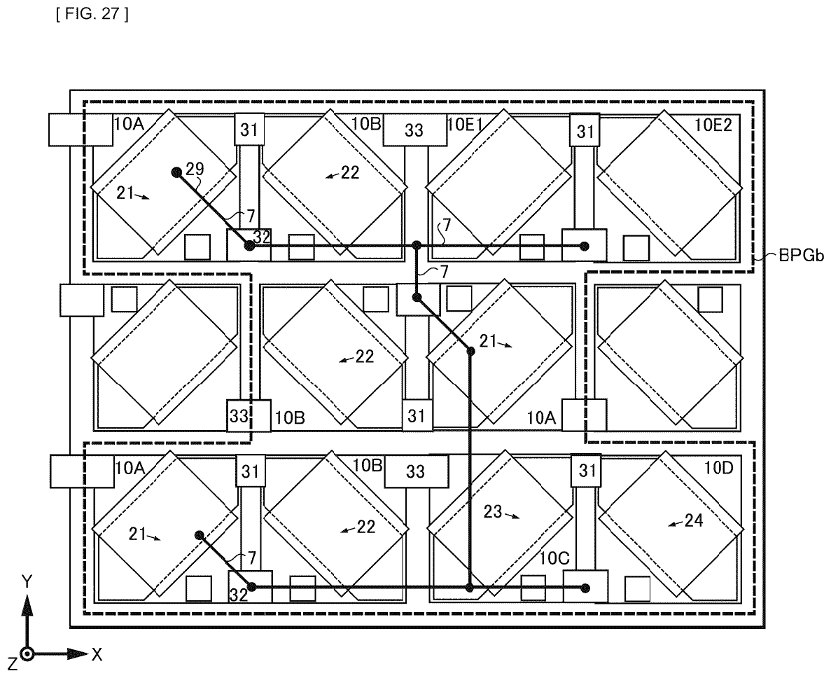

FIG. 26 illustrates an example of a planar layout configuration of the pixels 10 at which the red filter 41 is disposed.

In the sixth embodiment, a total of eight pixels 10 are constructed as one unit pixel BPR, and the red filter 41 is disposed at the unit pixel BPR.

To give detailed description, the unit pixel BPR includes three sets of the pixel 10A and the pixel 10B, and one set of the pixel 10C and the pixel 10D. The pixel 10A and the pixel 10B share the FD region 25, and are arranged to be adjacent to each other in the arrow-X direction. The one of the main electrodes 204 of the amplification transistor 21 disposed at the position corresponding to the pixel 10A and the one of the main electrodes 204 of the selection transistor 22 disposed at the position corresponding to the pixel 10B are electrically coupled to each other through the shared coupling section 31.

The three sets of the pixel 10A and the pixel 10B are disposed to be sequentially adjacent to each other in the arrow-Y direction. The pixel 10A and the pixel 10B in a second row are reversed and arranged to be shifted by one pixel 10, in the arrow-X direction with respect to the pixel 10A and the pixel 10B in a first row and a third row. The first row, the second row, and the third row are defined in the arrow-Y direction.

Here, the gate electrode 203 of the amplification transistor 21 and the shared coupling section 32 that couples the FD regions 25 to each other are electrically coupled to each other through the wiring 7. The wiring 7 extends obliquely to coincide with the direction of the gate width Wg of the amplification transistor 21. The direction of the gate width Wg is set to 45 degrees, in a similar manner to an inclination of the direction of the gate width Wg of the solid-state imaging device 1 according to the first embodiment.

The one set of the pixel 10C and the pixel 10D is arranged on the opposite side in the arrow-X direction with respect to the pixel 10A and the pixel 10B in the second row. The pixel 10C and the pixel 10D share the FD region 25, and are arranged to be adjacent to each other in the arrow-X direction. The one of the main electrodes 204 of the FD conversion gain switching transistor 23 disposed at the position corresponding to the pixel 10C and the one of the main electrodes 204 of the reset transistor 24 disposed at the position corresponding to the pixel 10D are electrically coupled to each other through the shared coupling section 31.

The blue filter 44 is disposed at a unit pixel BPB, as illustrated in FIG. 25. The unit pixel BPB is constructed by a total of eight pixels 10, in a similar manner to the unit pixel BPR.

### (4) Planar Layout Configuration of Green Filter (Blue Side) 43 and Green Filter (Red Side) 42

FIG. 27 illustrates an example of a planar layout configuration of the pixels 10 at which the green filter (blue side) 43 is disposed.

In the sixth embodiment, a total of ten pixels 10 are constructed as one unit pixel BPGb, and the green filter (blue side) 43 is disposed at the unit pixel BPGb.

To give detailed description, the unit pixel BPGb includes three sets of the pixel 10A and the pixel 10B, one set of the pixel 10C and the pixel 10D, and one set of a dummy pixel 10E1 and a dummy pixel 10E2. The pixel 10A and the pixel 10B share the FD region 25, and are arranged to be adjacent to each other in the arrow-X direction. The one of the main electrodes 204 of the amplification transistor 21 disposed at the position corresponding to the pixel 10A and the one of the main electrodes 204 of the selection transistor 22 disposed at the position corresponding to the pixel 10B are electrically coupled to each other through the shared coupling section 31.

The three sets of the pixel 10A and the pixel 10B are disposed to be sequentially adjacent to each other in the arrow-Y direction. The pixel 10A and the pixel 10B in the second row are reversed and arranged to be shifted by one pixel 10, in the arrow-X direction with respect to the pixel 10A and the pixel 10B in the first row and the third row. The first row, the second row, and the third row are defined in the arrow-Y direction.

Here, the gate electrode 203 of the amplification transistor 21 and the shared coupling section 32 that couples the FD regions 25 to each other are electrically coupled to each other through the wiring 7. The wiring 7 extends obliquely to coincide with the direction of the gate width Wg of the amplification transistor 21.

The one set of the pixel 10C and the pixel 10D is arranged in the arrow-X direction with respect to the pixel 10A and the pixel 10B in the first row. The pixel 10C and the pixel 10D share the FD region 25, and are arranged to be adjacent to each other in the arrow-X direction. The one of the main electrodes 204 of the FD conversion gain switching transistor 23 disposed at the position corresponding to the pixel 10C and the one of the main electrodes 204 of the reset transistor 24 disposed at the position corresponding to the pixel 10D are electrically coupled to each other through the shared coupling section 31.

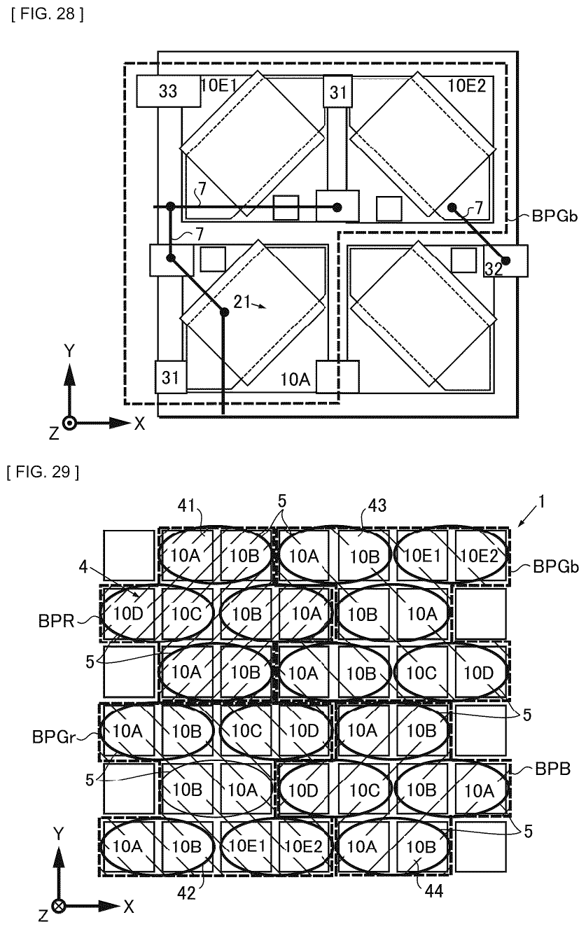

FIG. 28 illustrates an example of a planar layout configuration of the dummy pixel 10E1 and the dummy pixel 10E2.

The one set of the dummy pixel 10E1 and the pixel 10E2 is arranged in the arrow-X direction with respect to the pixel 10A and the pixel 10B in the third row. The dummy pixel 10E1 and the pixel 10E2 have a configuration similar to that of the pixel 10A and the pixel 10B.

The dummy pixel 10E1 that is one of the dummy pixels arranged in the unit pixel BPGb is coupled to the wiring 7 to be coupled to the FD region 25 in the unit pixel BPGb. The dummy pixel 10E2 that is another one of the dummy pixels arranged in the unit pixel BPGb is coupled to the wiring 7 to be coupled to the FD region 25 in the unit pixel BPR. The wiring 7 is coupled to the main electrode 204 of the transistor 200 of the dummy pixel 10E2.

That is, the dummy pixel 10E1 and the dummy pixel 10E2 uniformly adjust each of parasitic capacitance to be added to the FD region 25 of the unit pixel BPGb and parasitic capacitance to be added to the FD region 25 of the unit pixel BPR.

The green filter (red side) 42 is disposed at a unit pixel BPGr, as illustrated in FIG. 25. The unit pixel BPGr is constructed by a total of ten pixels 10, in a similar manner to the unit pixel BPGb.

The unit pixel BPGr has substantially the same configuration as the configuration of the unit pixel BPGb except that a disposition position of the pixel 10C and the pixel 10D and a disposition position of the dummy pixel 10E1 and the dummy pixel 10E2 are reversed in the arrow-Y direction.

The dummy pixel 10E1 that is one of the dummy pixels arranged in the unit pixel BPGr is coupled to the wiring 7 to be coupled to the FD region 25 in the unit pixel BPGr. The dummy pixel 10E2 that is another one of the dummy pixels arranged in the unit pixel BPGr is coupled to the wiring 7 to be coupled to the FD region 25 in the unit pixel BPB.

### (5) Layout Configuration of Optical Lens 5

FIG. 29 illustrates an example of a planar layout configuration of the optical lenses 5 to be disposed at the pixels 10.

In the sixth embodiment, the optical lens 5 is disposed on the first surface of the base 15 with the color filter 4 interposed therebetween. The optical lens 5 is formed to have a length corresponding to two pixels 10 in the arrow-X direction, and is formed to have a length corresponding to one pixel 10 in the arrow-Y direction. That is, the optical lens 5 is formed in an elliptical shape having a different aspect ratio in a plan view.

One optical lens 5 is disposed to correspond to the one set of the pixel 10A and the pixel 10B. Similarly, one optical lens 5 is disposed to correspond to the one set of the pixel 10C and the pixel 10D. In addition, one optical lens 5 is disposed to correspond to the one set of the dummy pixel 10E1 and the pixel 10E2.

Components other than the above-described components are components the same or substantially the same as the components of the solid-state imaging device 1 according to the fifth embodiment.

### [Workings and Effects]

The solid-state imaging device 1 according to the sixth embodiment makes it possible to achieve workings and effects similar to the workings and effects achievable by the solid-state imaging device 1 according to the fifth embodiment.

Further, the solid-state imaging device 1 includes the unit pixel BPR at which the red filter 41 is to be disposed, the unit pixel BPB at which the blue filter 44 is to be disposed, the unit pixel BPGr at which the green filter (red side) 42 is to be disposed, and the unit pixel BPGb at which the green filter (blue side) 43 is to be disposed. The solid-state imaging device 1 allows all pixel phase difference signals to be acquired in two unit pixels BP sharing the FD region 25. This enables the number of FD additions to vary depending on an accumulation time. This enables the solid-state imaging device 1 to have a high dynamic range rendering (HDR) function.

Furthermore, in the solid-state imaging device 1, a basic unit of the two pixels 10 is shifted in the oblique direction, here, in a 45 degree direction. This makes it possible to achieve V2 times resolution by performing remosaic processing of color arrangements.

In addition, in the solid-state imaging device 1, the plurality of sets of the pixel 10A and the pixel 10B is disposed for the one set of the pixel 10C and the pixel 10D. That is, the area of the amplification transistor 21 disposed in the pixel 10A increases. This enables the solid-state imaging device 1 to have improved noise resistance.

It is to be noted that the number of the sets of the pixel 10A and the pixel 10B is appropriately changeable with respect to the number of the sets of the pixel 10C and the pixel 10D on the basis of balance of a pixel characteristic in the sixth embodiment.

Moreover, in the solid-state imaging device 1, one set of the pixels 10 among the five sets of the pixels 10 on sides of the unit pixel BPGr and the unit pixel BPGb is configured as the dummy pixel 10E1 and the dummy pixel 10E2. The dummy pixel 10E1 is coupled to the FD region 25 in the unit pixel BPGr or the unit pixel BPGb. The dummy pixel 10E2 is coupled to the FD region 25 in the unit pixel BPB or the unit pixel BPR. Therefore, it is possible to make uniform the number of the pixels to be coupled to the FD region 25. This makes it possible to equalize the parasitic capacitance to be added to the FD region 25.

Further, the wiring 7 that couples the FD regions 25 to each other is routed partially obliquely, as illustrated in FIGS. 24, 26, and 27. This helps to shorten a wiring length of the wiring 7. This makes it possible to reduce the parasitic capacitance to be added to the wiring 7.

### 7. Example of Practical Application to Mobile Body

A technique according to the present disclosure (the present technology) is applicable to various products. For example, the technique according to the present disclosure may be achieved as an apparatus to be mounted on any type of mobile body such as an automobile, an electric vehicle, a hybrid electric vehicle, a motorcycle, a bicycle, a personal mobility, an airplane, a drone, a vessel, or a robot.

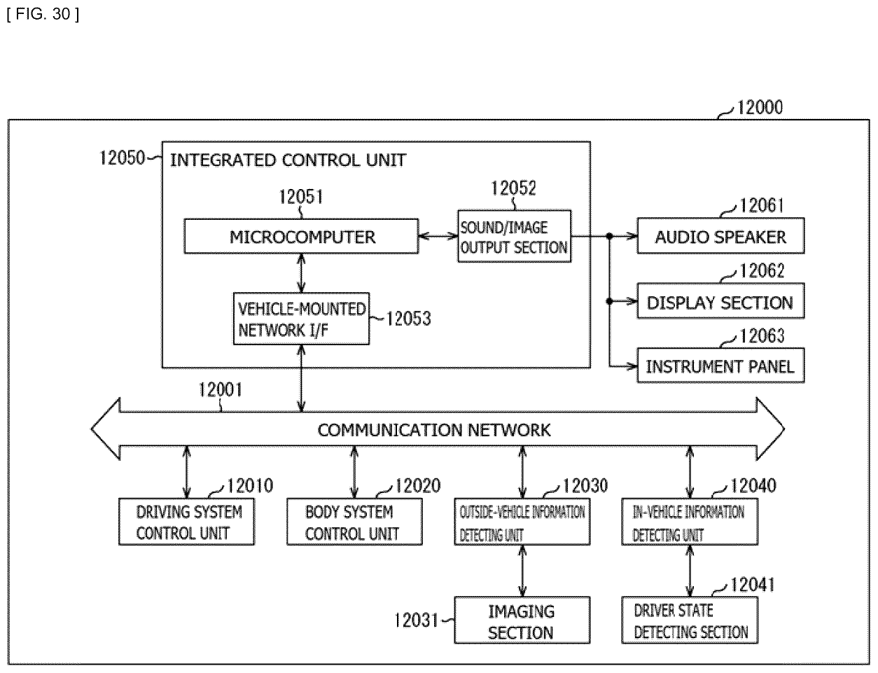

FIG. 30 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 30, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 30, an audio speaker 12061, a display section 12062, and an instrument panel 12063 are illustrated as the output device. The display section 12062 may, for example, include at least one of an on-board display and a head-up display.

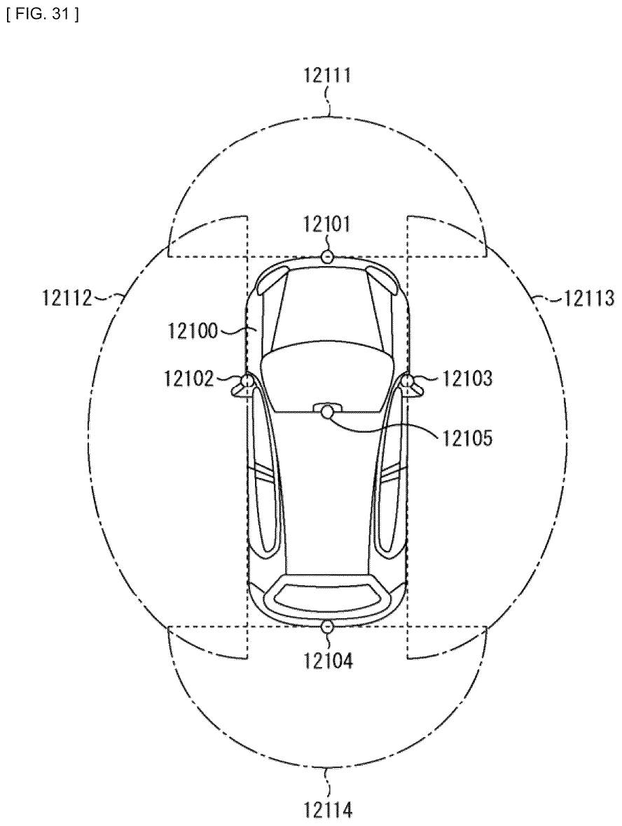

FIG. 31 is a diagram depicting an example of the installation position of the imaging section 12031.

In FIG. 31, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 31 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of an example of the vehicle control system to which the technique according to the present disclosure is applicable. The technique according to the present disclosure is applicable to the imaging section 12031, of the configurations described above. Applying the technique according to the present disclosure to the imaging section 12031 enables achievement of the imaging section 12031 having a simpler configuration.

### 8. Other Embodiments

The present technology is not limited to the above-described embodiments, and may be modified in a variety of ways without departing from the gist thereof.

For example, solid-state imaging devices according to two or more embodiments may be combined among the solid-state imaging devices according to the first embodiment to the sixth embodiment described above.

Further, for example, it is possible to appropriately change the number of the sets of the pixels constructing the unit pixel or an arrangement layout of the unit pixels in the solid-state imaging device according to the sixth embodiment, in the present technology.

Furthermore, it is possible to widely apply the present technology not only to an imaging application but also to a light receiving device, a photoelectric conversion device, a photodetector, or the like used for a sensing application or the like. Moreover, the solid-state imaging device may use not only incident light of visible light but also incident light of infrared light, ultraviolet light, electromagnetic waves, or the like. In addition, the present technology may have a configuration in which a band pass filter or the like is optionally provided above the photoelectric conversion element on the light incident side to receive desired incident light.

In the present technology, a solid-state imaging device includes a first pixel, a second pixel, a first transistor, a second transistor, and a pixel separation region.

The first pixel includes a first photoelectric conversion element that is disposed on a side of a first surface of a base and that converts light into electric charge. The side of the first surface is a light incident side. The second pixel is adjacent to the first pixel. The second pixel includes a second photoelectric conversion element that is disposed on the side of the first surface of the base and that converts light into electric charge.

The first transistor is disposed at a position corresponding to the first pixel on a side of a second surface of the base, processes the converted electric charge, and includes a pair of main electrodes. The side of the second surface is a side opposite to the first surface. The second transistor is disposed at a position corresponding to the second pixel on the side of the second surface of the base, processes the converted electric charge, and includes a pair of main electrodes.

The pixel separation region is disposed between the first photoelectric conversion element and the first transistor and between the second photoelectric conversion element and the second transistor. The pixel separation region electrically and optically separates the first photoelectric conversion element and the first transistor from each other and electrically and optically separates the second photoelectric conversion element and the second transistor from each other.

In addition, the solid-state imaging device further includes a shared coupling section. One end of the shared coupling section is electrically coupled directly to one of the main electrodes of the first transistor. Another end of the shared coupling section is electrically coupled, across the pixel separation region, directly to one of the main electrodes of the second transistor.

Such a configuration makes it possible to secure an area sufficient to dispose each of the first transistor and the second transistor in a corresponding one of the first pixel and the second pixel. In addition, it is possible to construct the first transistor and the second transistor having excellent noise resistance, thus enabling improvement in electrical reliability of the solid-state imaging device.

### <Configuration of Present Technology>

The present technology has the following configuration. According to the present technology of the following configuration, a solid-state imaging device makes it possible to improve electrical reliability while securing an area sufficient to dispose a transistor in a pixel.

(1)

A solid-state imaging device including:
a first pixel including a first photoelectric conversion element that is disposed on a side of a first surface of a base and converts light into electric charge, the side of the first surface being a light incident side;
a second pixel being adjacent to the first pixel, and including a second photoelectric conversion element that is disposed on the side of the first surface of the base and converts light into electric charge;
a first transistor disposed at a position corresponding to the first pixel on a side of a second surface of the base, the first transistor including a pair of main electrodes, the side of the second surface being a side opposite to the first surface;
a second transistor disposed at a position corresponding to the second pixel on the side of the second surface of the base, the second transistor including a pair of main electrodes;
a pixel separation region disposed between the first photoelectric conversion element and the first transistor and between the second photoelectric conversion element and the second transistor, the pixel separation region electrically and optically separating the first photoelectric conversion element and the first transistor from each other and electrically and optically separating the second photoelectric conversion element and the second transistor from each other; and
a shared coupling section having one end electrically coupled directly to one of the main electrodes of the first transistor, and another end electrically coupled, across the pixel separation region, directly to one of the main electrodes of the second transistor.
   (2)

The solid-state imaging device according to (1), in which
the one end of the shared coupling section is directly coupled to a side surface of the one of the main electrodes of the first transistor, and
the other end of the shared coupling section is directly coupled to a side surface of the one of the main electrodes of the second transistor.
   (3)

The solid-state imaging device according to (1) or (2), in which the shared coupling section is embedded in a shared trench formed from the second surface of the pixel separation region toward the first surface of the pixel separation region.

(4)

The solid-state imaging device according to (1), in which
the one end of the shared coupling section is directly coupled to a surface of the one of the main electrodes of the first transistor, and
the other end of the shared coupling section is directly coupled to a surface of the one of the main electrodes of the second transistor.
   (5)

The solid-state imaging device according to (4), in which the shared coupling section is formed to intersect the pixel separation region on the second surface of the base.

(6)

The solid-state imaging device according to any one of (1) to (5), in which the shared coupling section includes a gate electrode material.

(7)

The solid-state imaging device according to any one of (1) to (6), in which the pixel separation region has a first trench having a depth direction in a thickness direction of the base, and includes a first embedded member embedded in the first trench.

(8)

The solid-state imaging device according to (7), in which each of the first transistor and the second transistor is surrounded by an element separation region having a second trench and including a second embedded member and is electrically separated from another region, the second trench being formed from the second surface of the base toward the side of the first surface of the base and having a depth shallower than that of the first trench, the second embedded member being embedded in the second trench.

(9)

The solid-state imaging device according to any one of (1) to (8), in which a direction of a gate length of each of the first transistor and the second transistor is oblique to an extending direction of the pixel separation region.

(10)

The solid-state imaging device according to any one of (1) to (9), in which a direction of a gate length of each of the first transistor and the second transistor is formed at an angle of 45 degrees with respect to an extending direction of the pixel separation region.

(11)

The solid-state imaging device according to any one of (1) to (10), in which at least one of a floating diffusion region, a control electrode of a transfer transistor, or a base coupling section is disposed in a direction of a gate width of each of the first transistor and the second transistor, the floating diffusion region transferring the converted electric charge, the control electrode controlling the transferring of the electric charge, the base coupling section supplying the base with a voltage.

(12)

The solid-state imaging device according to any one of (1) to (11), in which the first transistor and the second transistor respectively include an amplification transistor and a selection transistor.

(13)

The solid-state imaging device according to any one of (1) to (11), in which the first transistor and the second transistor construct a pixel circuit that processes the converted electric charge.

(14)

The solid-state imaging device according to any one of (1) to (13), further including:
a third pixel including a third photoelectric conversion element that is disposed on the side of the first surface of the base and converts light into electric charge;
a fourth pixel being adjacent to the third pixel, and including a fourth photoelectric conversion element that is disposed on the side of the first surface of the base and converts light into electric charge;
a third transistor disposed at a position corresponding to the third pixel on the side of the second surface of the base, the third transistor including a pair of main electrodes;
a fourth transistor disposed at a position corresponding to the fourth pixel on the side of the second surface of the base, the fourth transistor including a pair of main electrodes; and
a shared coupling section having one end electrically coupled directly to one of the main electrodes of the third transistor, and another end electrically coupled, across the pixel separation region, directly to one of the main electrodes of the fourth transistor.
   (15)

The solid-state imaging device according to (14), in which the third transistor and the fourth transistor respectively include a floating diffusion conversion gain switching transistor and a reset transistor.

(16)

The solid-state imaging device according to (14) or (15), in which
the first pixel and the second pixel are arranged to be adjacent to each other in a first direction, and
the third pixel and the fourth pixel are arranged to be adjacent to the first pixel and the second pixel in a second direction intersecting the first direction and to be adjacent to each other in the first direction.
   (17)

The solid-state imaging device according to (16), in which
a planar shape of the first transistor and the second transistor is a shape formed in line symmetry with respect to the pixel separation region disposed between both the first transistor and the second transistor, and
a planar shape of the third transistor and the fourth transistor is a shape formed in line symmetry with respect to the pixel separation region disposed between both the third transistor and the fourth transistor.
   (18)

The solid-state imaging device according to any one of (1) to (17), further including:
a color filter disposed across at least the first pixel and the second pixel in a first direction and having the same color; and
an optical lens disposed on a side of the color filter opposite to the first pixel and the second pixel, the optical lens having a length in a second direction shorter than a length in the first direction, the second direction intersecting the first direction, in which
another one of the first pixel and another one of the second pixel adjacent to the first pixel and the second pixel in the second direction are arranged to be shifted by one pixel in the first direction with respect to the first pixel and the second pixel.
   (19)

The solid-state imaging device according to any one of (1) to (17), further including a dummy pixel that adjusts capacitance of a floating diffusion region.

The present application claims the benefit of Japanese Priority Patent Application JP2022-020873 filed with the Japan Patent Office on Feb. 14, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A solid-state imaging device comprising:
a first pixel including a first photoelectric conversion element that is disposed on a side of a first surface of a base and converts light into electric charge, the side of the first surface being a light incident side;
a second pixel being adjacent to the first pixel, and including a second photoelectric conversion element that is disposed on the side of the first surface of the base and converts light into electric charge;
a first transistor disposed at a position corresponding to the first pixel on a side of a second surface of the base, the first transistor including a pair of main electrodes, the side of the second surface being a side opposite to the first surface;
a second transistor disposed at a position corresponding to the second pixel on the side of the second surface of the base, the second transistor including a pair of main electrodes;
a pixel separation region disposed between the first photoelectric conversion element and the first transistor and between the second photoelectric conversion element and the second transistor, the pixel separation region electrically and optically separating the first photoelectric conversion element and the first transistor from each other and electrically and optically separating the second photoelectric conversion element and the second transistor from each other; and
a shared coupling section having one end electrically coupled directly to one of the main electrodes of the first transistor, and another end electrically coupled, across the pixel separation region, directly to one of the main electrodes of the second transistor.

2. The solid-state imaging device according to claim 1, wherein
the one end of the shared coupling section is directly coupled to a side surface of the one of the main electrodes of the first transistor, and
the other end of the shared coupling section is directly coupled to a side surface of the one of the main electrodes of the second transistor.

3. The solid-state imaging device according to claim 2, wherein the shared coupling section is embedded in a shared trench formed from the second surface of the pixel separation region toward the first surface of the pixel separation region.

4. The solid-state imaging device according to claim 1, wherein
the one end of the shared coupling section is directly coupled to a surface of the one of the main electrodes of the first transistor, and
the other end of the shared coupling section is directly coupled to a surface of the one of the main electrodes of the second transistor.

5. The solid-state imaging device according to claim 4, wherein the shared coupling section is formed to intersect the pixel separation region on the second surface of the base.

6. The solid-state imaging device according to claim 1, wherein the shared coupling section includes a gate electrode material.

7. The solid-state imaging device according to claim 1, wherein the pixel separation region has a first trench having a depth direction in a thickness direction of the base, and includes a first embedded member embedded in the first trench.

8. The solid-state imaging device according to claim 7, wherein each of the first transistor and the second transistor is surrounded by an element separation region having a second trench and including a second embedded member and is electrically separated from another region, the second trench being formed from the second surface of the base toward the side of the first surface of the base and having a depth shallower than that of the first trench, the second embedded member being embedded in the second trench.

9. The solid-state imaging device according to claim 8, wherein a direction of a gate length of each of the first transistor and the second transistor is oblique to an extending direction of the pixel separation region.

10. The solid-state imaging device according to claim 8, wherein a direction of a gate length of each of the first transistor and the second transistor is formed at an angle of 45 degrees with respect to an extending direction of the pixel separation region.

11. The solid-state imaging device according to claim 10, wherein at least one of a floating diffusion region, a control electrode of a transfer transistor, or a base coupling section is disposed in a direction of a gate width of each of the first transistor and the second transistor, the floating diffusion region transferring the converted electric charge, the control electrode controlling the transferring of the electric charge, the base coupling section supplying the base with a voltage.

12. The solid-state imaging device according to claim 1, wherein the first transistor and the second transistor respectively comprise an amplification transistor and a selection transistor.

13. The solid-state imaging device according to claim 1, wherein the first transistor and the second transistor construct a pixel circuit that processes the converted electric charge.

14. The solid-state imaging device according to claim 1, further comprising:
a third pixel including a third photoelectric conversion element that is disposed on the side of the first surface of the base and converts light into electric charge;
a fourth pixel being adjacent to the third pixel, and including a fourth photoelectric conversion element that is disposed on the side of the first surface of the base and converts light into electric charge;
a third transistor disposed at a position corresponding to the third pixel on the side of the second surface of the base, the third transistor including a pair of main electrodes;
a fourth transistor disposed at a position corresponding to the fourth pixel on the side of the second surface of the base, the fourth transistor including a pair of main electrodes; and
a shared coupling section having one end electrically coupled directly to one of the main electrodes of the third transistor, and another end electrically coupled, across the pixel separation region, directly to one of the main electrodes of the fourth transistor.

15. The solid-state imaging device according to claim 14, wherein the third transistor and the fourth transistor respectively comprise a floating diffusion conversion gain switching transistor and a reset transistor.

16. The solid-state imaging device according to claim 14, wherein
the first pixel and the second pixel are arranged to be adjacent to each other in a first direction, and
the third pixel and the fourth pixel are arranged to be adjacent to the first pixel and the second pixel in a second direction intersecting the first direction and to be adjacent to each other in the first direction.

17. The solid-state imaging device according to claim 16, wherein
a planar shape of the first transistor and the second transistor is a shape formed in line symmetry with respect to the pixel separation region disposed between both the first transistor and the second transistor, and
a planar shape of the third transistor and the fourth transistor is a shape formed in line symmetry with respect to the pixel separation region disposed between both the third transistor and the fourth transistor.

18. The solid-state imaging device according to claim 1, further comprising:
a color filter disposed across at least the first pixel and the second pixel in a first direction and having the same color; and
an optical lens disposed on a side of the color filter opposite to the first pixel and the second pixel, the optical lens having a length in a second direction shorter than a length in the first direction, the second direction intersecting the first direction, wherein
another one of the first pixel and another one of the second pixel adjacent to the first pixel and the second pixel in the second direction are arranged to be shifted by one pixel in the first direction with respect to the first pixel and the second pixel.

19. The solid-state imaging device according to claim 1, further comprising a dummy pixel that adjusts capacitance of a floating diffusion region.
